(19) United States
(12) Patent Application Publication
(10) Pub. No.: US 2025/0062151 A1
(43) Pub. Date: Feb. 20, 2025

(54) MANUFACTURING METHOD OF ELECTRONIC DEVICE

(71) Applicant: InnoLux Corporation, Miao-Li County (TW)

(72) Inventors: Fang-Ying Lin, Miao-Li County (TW); Kai Cheng, Miao-Li County (TW); Ming-Chang Lin, Miao-Li County (TW); Tsau-Hua Hsieh, Miao-Li County (TW); Jian-Jung Shih, Miao-Li County (TW); Shu-Ming Kuo, Miao-Li County (TW)

(73) Assignee: InnoLux Corporation, Miao-Li County (TW)

(21) Appl. No.: 18/935,636

(22) Filed: Nov. 3, 2024

Related U.S. Application Data
(63) Continuation-in-part of application No. 18/376,002, filed on Oct. 3, 2023.
(60) Provisional application No. 63/422,443, filed on Nov. 4, 2022.
(60) Provisional application No. 63/621,090, filed on Jan. 15, 2024.

(30) Foreign Application Priority Data
Jul. 3, 2023 (CN) 202310798809.2
Sep. 18, 2024 (CN) 202411299135.2

(51) Int. Cl. H01L 21/683; H01L 25/075; H01L 33/00; H01L 33/62

(52) U.S. Cl. CPC H01L 21/6835; H01L 25/0753; H01L 33/0095; H01L 33/62; H01L 2221/68354; H01L 2221/68368; H01L 2933/0066

(57) ABSTRACT

A manufacturing method of an electronic device is disclosed by the present disclosure. The manufacturing method includes providing a plurality of semiconductor elements; performing a packaging process on the plurality of semiconductor elements to form a plurality of packaged semiconductor elements, wherein the packaging process includes disposing a plurality of filling material layers respectively on a sidewall of each of the plurality of semiconductor elements; providing a substrate, wherein the substrate includes a plurality of working areas, and each of the plurality of working areas includes at least one first recess; and disposing the plurality of packaged semiconductor elements in the at least one first recess of each of the plurality of working areas through fluid transfer.

### CROSS REFERENCE TO RELATED APPLICATIONS

This application is a continuation-in-part of U.S. application Ser. No. 18/376,002, filed on Oct. 3, 2023, which claims the benefit of U.S. Provisional Application No. 63/422,443, filed on Nov. 4, 2022. Further, this application claims the benefit of U.S. Provisional Application No. 63/621,090, filed on Jan. 15, 2024. The contents of these applications are incorporated herein by reference.

### BACKGROUND OF THE DISCLOSURE

### 1. Field of the Disclosure

The present disclosure relates to a manufacturing method of an electronic device, and more particularly to a manufacturing method of an electronic device including liquid transfer process.

### 2. Description of the Prior Art

Electronic elements can be transferred to the target substrate through massive transfer. However, in recent massive transfer technique, randomness of the distribution of electronic elements on the target substrate may be insufficient when the stamp transfer is used to transfer electronic components, such that the performance of the electronic elements on the target substrate would be different in different regions. That is, the performance may be not uniform, and the performance of the product may be reduced. In another aspect, the problem that the electronic elements may not be completely transferred may occur when the stamp transfer is used, thereby increasing production cost. Therefore, to improve the performance of the electronic device formed through massive transfer or to reduce the production cost of the electronic device formed through massive transfer is still an important issue in the present field.

### SUMMARY OF THE DISCLOSURE

The present disclosure aims at providing a manufacturing method of an electronic device.

In some embodiments, a manufacturing method of an electronic device is provided by the present disclosure. The manufacturing method includes providing a plurality of semiconductor elements; performing a packaging process on the plurality of semiconductor elements to form a plurality of packaged semiconductor elements, wherein the packaging process includes disposing a plurality of filling material layers respectively on a sidewall of each of the plurality of semiconductor elements; providing a substrate, wherein the substrate includes a plurality of working areas, and each of the plurality of working areas includes at least one first recess; and disposing the plurality of packaged semiconductor elements in the at least one first recess of each of the plurality of working areas through fluid transfer.

In some embodiments, a manufacturing method of an electronic device is provided by the present disclosure. The manufacturing method includes providing a plurality of semiconductor elements; performing a packaging process on the plurality of semiconductor elements to form a plurality of packaged semiconductor elements, wherein the packaging process includes disposing a plurality of filling material layers respectively on a sidewall of each of the plurality of semiconductor elements; providing a first substrate, wherein the first substrate includes a plurality of recesses; disposing the plurality of packaged semiconductor elements in the plurality of recesses of the first substrate through fluid transfer; providing a second substrate, wherein the second substrate includes a plurality of working areas; and transferring at least a portion of the plurality of packaged semiconductor elements from at least a portion of the plurality of recesses of the first substrate to the plurality of working areas.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 shows the flow chart of a manufacturing method of an electronic device according to a first embodiment of the present disclosure.

FIG. 2 schematically illustrates the fluid transfer process according to the first embodiment of the present disclosure.

FIG. 3 schematically illustrates top views of a substrate and electronic units according to the first embodiment of the present disclosure.

FIG. 4 schematically illustrates disposition of repairing electronic units according to the first embodiment of the present disclosure.

FIG. 5 schematically illustrates disposition of repairing electronic units according to a variant embodiment of the first embodiment of the present disclosure.

FIG. 6 schematically illustrates top views of the substrate and the electronic units after the repairing process according to the first embodiment of the present disclosure.

FIG. 7 shows the flow chart of a manufacturing method of an electronic device according to a second embodiment of the present disclosure.

FIG. 8 schematically illustrates the transfer of electronic units from a first substrate through stamp transfer.

FIG. 9 schematically illustrates the fluid transfer process according to the second embodiment of the present disclosure.

FIG. 10 schematically illustrates transfer of the electronic units from a second substrate to a third substrate according to the second embodiment of the present disclosure.

FIG. 11 schematically illustrates transfer of the electronic units from the second substrate to the third substrate according to a variant embodiment of the second embodiment of the present disclosure.

FIG. 12 schematically illustrates a cross-sectional view of the electronic device according to the second embodiment of the present disclosure.

FIG. 13 schematically illustrates top views of the substrate and the electronic units according to the second embodiment of the present disclosure.

FIG. 14 shows the flow chart of a manufacturing method of an electronic unit of an electronic device according to an embodiment of the present disclosure.

FIG. 15 schematically illustrates the manufacturing process of an electronic unit of an electronic device according to an embodiment of the present disclosure.

FIG. 16 schematically illustrates a cross-sectional view of an electronic unit of an electronic device according to an embodiment of the present disclosure.

FIG. 17 schematically illustrates a cross-sectional view of an electronic unit of an electronic device according to another embodiment of the present disclosure.

FIG. 18 schematically illustrates the fluid transfer process according to a variant embodiment of the second embodiment of the present disclosure.

FIG. 19 shows a schematic diagram of applying the electronic device of the present disclosure to a vehicle display.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within +20%, +10%, +5%, +3%, +2%, +1%, or +0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device of the present disclosure may be any suitable device applied to the above-mentioned devices. The electronic device may be a foldable electronic device, a flexible electronic device or a stretchable electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may for example include a biosensor, a touch sensor, a fingerprint sensor, other suitable sensors or combinations of the above-mentioned sensors. The antenna device may for example include a liquid crystal antenna device or a non-liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic elements, wherein the electronic elements may include passive elements or active elements, such as capacitor, resistor, inductor, diode, transistor, sensors, and the like. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. It should be noted that the electronic device may be arrangements of the above-mentioned devices, but the present disclosure is not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices.

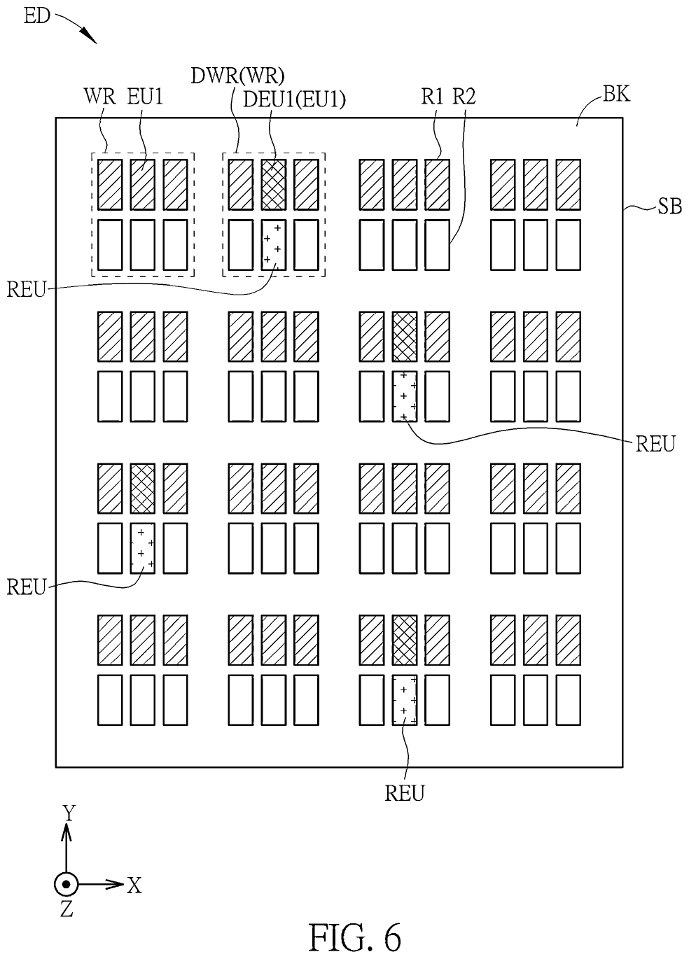

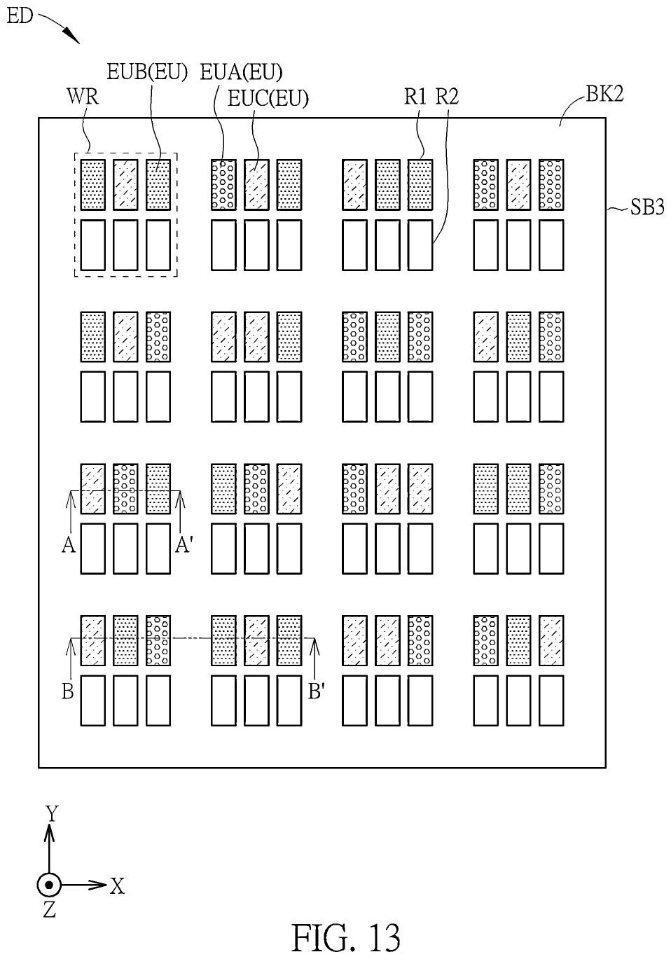

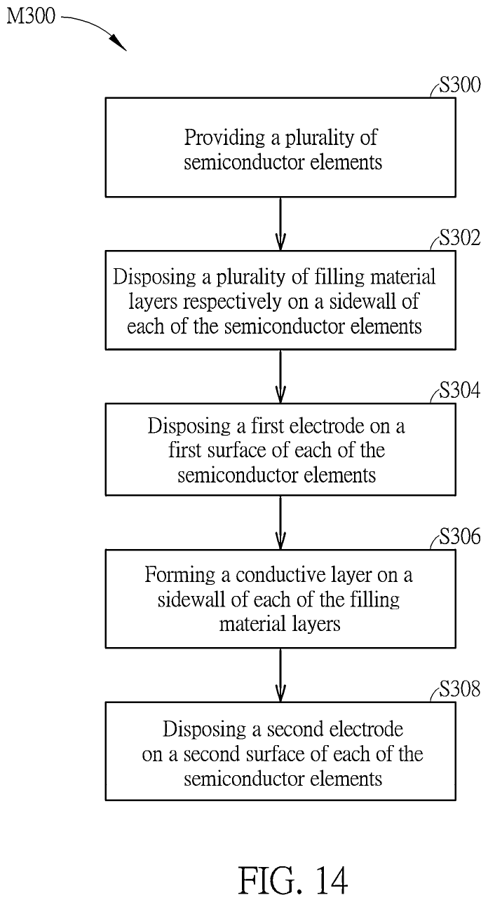

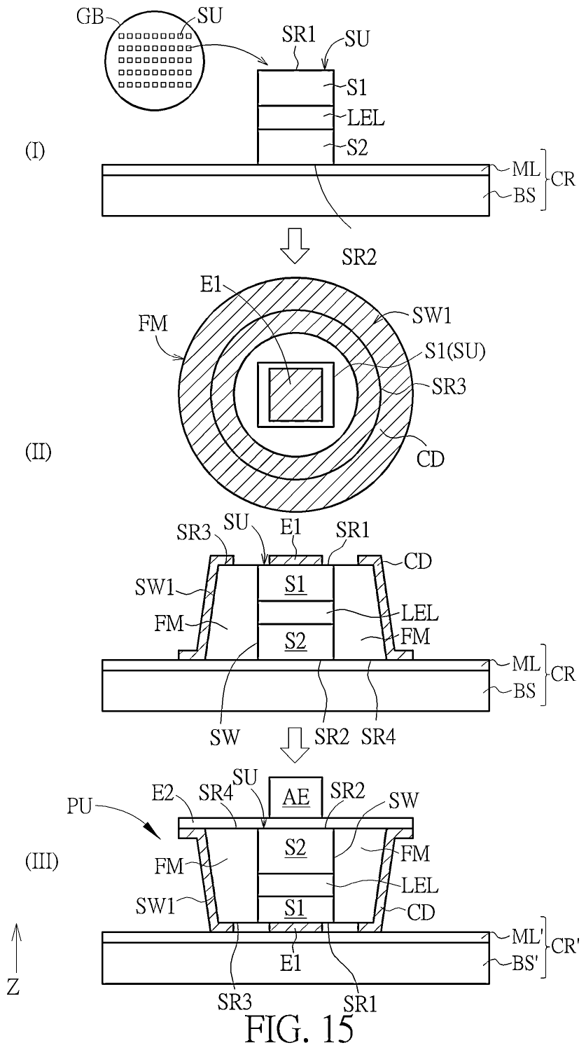

Referring to FIG. 14 to FIG. 16, FIG. 14 shows the flow chart of a manufacturing method of an electronic unit of an electronic device according to an embodiment of the present disclosure, FIG. 15 schematically illustrates the manufacturing process of an electronic unit of an electronic device according to an embodiment of the present disclosure, and FIG. 16 schematically illustrates a cross-sectional view of an electronic unit of an electronic device according to an embodiment of the present disclosure. According to the present disclosure, the electronic unit (such as the electronic unit EU shown in FIG. 6 and FIG. 13) of the electronic device (such as the electronic device ED shown in FIG. 6 and FIG. 13) includes a packaged semiconductor element PU. The packaged semiconductor element PU includes a semiconductor element SU. The semiconductor element SU may be any suitable element including a semiconductor layer or formed through a semiconductor process. The semiconductor element SU may include any suitable element according to the type or use of the electronic device. For example, in an embodiment, the electronic device may include a display device, and the semiconductor element SU may include a light emitting unit, wherein the light emitting unit for example includes a light emitting diode, but not limited thereto. In some embodiments, the electronic device may include a sensing device, and the semiconductor element SU may include any suitable sensing unit, such as a photodiode, but not limited thereto. The light emitting diode is taken as an example of the semiconductor element SU for describing the manufacturing method of the electronic device in the following. Specifically, the packaged semiconductor element PU may be formed by performing a packaging process on the semiconductor element SU. After the packaged semiconductor element PU is formed, the packaged semiconductor element PU may be transferred to the target substrate (such as the substrate SB shown in FIG. 6 or the third substrate SB3 shown in FIG. 13) through a fluid transfer process to form the electronic device. In other words, a packaging process may be performed on the semiconductor element to form the packaged semiconductor element PU at first, and then the packaged semiconductor element PU may be transferred to the target substrate through the fluid transfer process to form the electronic device. According to the present embodiment, the manufacturing method M300 of the packaged semiconductor element PU may include follow steps:
S300: providing a plurality of semiconductor elements;
S302: disposing a plurality of filling material layers respectively on a sidewall of each of the semiconductor elements;
S304: disposing a first electrode on a first surface of each of the semiconductor elements;
S306: forming a conductive layer on a sidewall of each of the filling material layers;
S308: disposing a second electrode on a second surface of each of the semiconductor elements.

The steps of the manufacturing method M300 of the packaged semiconductor element PU will be detailed in the following.

The manufacturing method M300 of the packaged semiconductor element PU may include performing the step S300: providing a plurality of semiconductor elements SU at first. In detail, as shown in the process (I) of FIG. 15, a substrate GB and a plurality of semiconductor elements SU disposed on the substrate GB may be provided at first. The substrate GB may include a growth substrate, but not limited thereto. For example, the semiconductor elements SU may be formed on the substrate GB through an epitaxial process. In some embodiments, the substrate GB may be used to carry the semiconductor elements SU or provide a supporting function for the semiconductor elements SU. After that, the plurality of semiconductor elements SU may be transferred from the substrate GB to a carrier CR. In the present embodiment, the semiconductor elements SU may be transferred from the substrate GB to the carrier CR by stamp transfer, but not limited thereto. For example, the semiconductor elements SU may be picked up at a specific interval on the substrate GB and transferred to the carrier CR, such that the specific interval may be included between two adjacent semiconductor elements SU on the carrier CR, which is beneficial for the subsequent packaging process of the semiconductor elements SU. In some embodiments, the semiconductor elements SU may be transferred from the substrate GB to the carrier CR by laser transfer. The carrier CR may include a base BS and a material layer ML disposed on the base BS, and the semiconductor elements SU may be adhered to the base BS through the material layer ML. The base BS may include a rigid base or a flexible base. The rigid base for example includes glass, quartz, sapphire, ceramic, other suitable materials or combinations of the above-mentioned materials, and the flexible base for example includes polyimide (PI), polycarbonate (PC), polyethylene terephthalate (PET), other suitable materials or combinations of the above-mentioned materials, but not limited thereto. The material layer ML may include any suitable material having temporary adhesion to the semiconductor elements SU, such that the semiconductor elements SU may be temporarily fixed on the base BS. In the present embodiment, the semiconductor element SU may include a light emitting diode, such as an inorganic light emitting diode, but not limited thereto. For example, the semiconductor element SU may include a first semiconductor layer S1, a second semiconductor layer S2 and a light emitting layer LEL disposed between the first semiconductor layer S1 and the second semiconductor layer S2. Specifically, the semiconductor element SU may include a structure formed by stacking the second semiconductor layer S2, the light emitting layer LEL and the first semiconductor layer S1 in sequence along the normal direction (that is, the direction Z) of the carrier CR, wherein the second semiconductor layer S2 may contact the material layer ML, but not limited thereto. In some embodiments, the semiconductor element SU may include a structure formed by stacking the first semiconductor layer S1, the light emitting layer LEL and the second semiconductor layer S2 in sequence along the normal direction of the carrier CR, wherein the first semiconductor layer S1 may contact the material layer ML. The semiconductor element SU may further include other suitable layers, such as an ohmic contact layer, which is not limited to the above-mentioned layers. The semiconductor element SU includes a first surface SR1 and a second surface SR2 opposite to the first surface SR1, wherein the first surface SR1 may be a surface of the semiconductor element SU away from the carrier CR, and the second surface SR2 may be a surface of the semiconductor element SU adjacent to the carrier CR, or a surface of the semiconductor element SU contacting the material layer ML. In the present embodiment, the first surface SR1 may be the surface of the first semiconductor layer S1, and the second surface SR2 may be the surface of the second semiconductor layer S2. It should be noted that although the process (I) of FIG. 15 shows the structure in which only one semiconductor element SU is transferred to the carrier CR, the carrier CR may include the plurality of semiconductor elements SU transferred from the substrate GB according to the present disclosure.

After the semiconductor elements SU are transferred to the carrier CR, the step S302 may be performed to dispose a plurality of filling material layers FM respectively on a sidewall SW of each of the semiconductor elements SU. In detail, as shown in the process (II) of FIG. 15, the semiconductor element SU may include a sidewall SW connected between the first surface SR1 and the second surface SR2, and the filling material layer FM may be disposed on the carrier CR and surround the sidewall SW of the semiconductor element SU. In other words, as shown in the process (II) of FIG. 15, in a top view of the semiconductor element SU, the filling material layer FM may surround the semiconductor element SU. The filling material layer FM may cover the sidewall SW of the semiconductor element SU, but not cover the first surface SR1 and the second surface SR2 of the semiconductor element SU. Specifically, the filling material layer FM may include a third surface SR3 and a fourth surface SR4 opposite to the third surface SR3, the third surface SR3 is adjacent to the first surface SR1 of the semiconductor element SU, and the fourth surface SR4 is adjacent to the second surface SR2 of the semiconductor element SU, wherein in the normal direction of the carrier CR, the third surface SR3 may be substantially aligned with the first surface SR1, and the fourth surface SR4 may be substantially aligned with the second surface SR2, but not limited thereto. The filling material layer FM may include any suitable material with high light transmittance, such as acrylic, siloxane, silica, other suitable materials or combinations of the above-mentioned materials. In the present embodiment, the transmittance of the filling material layer FM for visible light may be greater than 90%.

According to the present embodiment, as shown in the process (II) of FIG. 15, in a top view of the filling material layer FM, the outer edges of the third surface SR3 and the fourth surface SR4 of the filling material layer FM may be circular or approximately circular (for example, elliptical, but not limited thereto). Therefore, the packaged semiconductor elements PU may have circular outlines in the top view of the electronic device ED (for example, viewed in a direction parallel to the direction Z). Specifically, the third surface SR3 (or the fourth surface SR4) has an annular shape, wherein the outer edge of the annular shape is circular or approximately circular, and the shape of the inner edge of the annular shape is the same as the shape of the semiconductor element SU. In a top view of the semiconductor element SU, the shape of the semiconductor element SU may include rectangle, circle, polygon, irregular shapes or other suitable shapes. For example, in the present embodiment, in a top view of the semiconductor element SU, the shape of the semiconductor element SU may be a rectangle, but not limited thereto. The filling material layer FM further includes a sidewall SW1 connected between the third surface SR3 and the fourth surface SR4. In some embodiments, the size (such as area) of the third surface SR3 and the size of the fourth surface SR4 may be different, for example, the size of the third surface SR3 may be less than the size of the fourth surface SR4, and the sidewall SW1 may not be perpendicular to the third surface SR3 and the fourth surface SR4, as shown in the process (II) of FIG. 15. In some other embodiments, the size of the third surface SR3 may be substantially the same as the size of the fourth surface SR4, and the sidewall SW1 may be perpendicular to the third surface SR3 and the fourth surface SR4. According to the shape design of the filling material layer FM, a semiconductor element SU and a filling material layer FM surrounding the semiconductor element SU may form a disk structure (or a cylindrical structure).

The manufacturing method M300 of the packaged semiconductor element PU of the present embodiment further includes the step S304: disposing a first electrode E1 on the first surface SR1 of each of the semiconductor elements SU. Specifically, after the semiconductor element SU is transferred to the carrier CR, the first electrode E1 may be disposed on the first surface SR1 of the semiconductor element SU away from the carrier CR. The first electrode E1 contacts the first surface SR1, that is, the first electrode E1 contacts the first semiconductor layer S1. The first electrode E1 may include any suitable conductive material, such as metal materials or transparent conductive materials. It should be noted that in some embodiments, after the semiconductor element SU is transferred to the carrier CR, the first electrode E1 may be disposed at first, and then the filling material layer FM is disposed. In some other embodiments, after the semiconductor element SU is transferred to the carrier CR, the filling material layer FM may be disposed at first, and then the first electrode E1 is disposed.

The manufacturing method M300 of the packaged semiconductor element PU of the present embodiment further includes the step S306: forming a conductive layer CD on the sidewall SW1 of each of the filling material layers FM. In detail, as shown in the process (II) of FIG. 15, after the filling material layer FM is disposed, the conductive layer CD may be formed along the sidewall SW1 of the filling material layer FM. The conductive layer CD may be disposed to surround the sidewall SW1 of the filling material layer FM, thereby covering the sidewall SW1 of the filling material layer FM. In the present embodiment, as shown in the process (II) of FIG. 15, the conductive layer CD may further extend on the third surface SR3 of the filling material layer FM, but not contact the first electrode E1 and the first semiconductor layer S1. In such condition, in a top view of the conductive layer CD, the portion of the conductive layer CD located on the third surface SR3 may have an annular structure, wherein the annular structure may expose the first electrode E1 and the first semiconductor layer S1. In some embodiments, the conductive layer CD may not extend on the third surface SR3 of the filling material layer FM, or the conductive layer CD may not contact the third surface SR3. For example, an end of the conductive layer CD adjacent to the third surface SR3 may substantially be aligned with the third surface SR3. In addition, although the process (II) of FIG. 15 shows the structure that the conductive layer CD further extends on the carrier CR (or on the material layer ML), it is not limited in the present embodiment. In some embodiments, the conductive layer CD may not extend on the carrier CR.

According to the present disclosure, the conductive layer CD may include materials with high reflectivity, or the conductive layer CD may at least partially include materials with high reflectivity. For example, in some embodiments, the material of the conductive layer CD may be a conductive material with high reflectivity, such as silver (Ag) or aluminum (Al), but not limited thereto. In some embodiments, the conductive layer CD may include a composite structure, wherein the composite structure includes a conductive material layer and a reflective material layer, and the reflective material layer is located between the conductive material layer and the sidewall SW1 of the filling material layer FM. The conductive material layer may include metal materials with high conductivity, such as gold (Au) or copper (Cu), but not limited thereto. The reflective material layer may include any suitable element or layer with high reflectivity, such as distributed bragg reflector (DBR), but not limited thereto. By making the conductive layer CD highly reflective, the light emitting effect of the packaged semiconductor element PU may be improved. It should be noted that in the manufacturing method M300, the step of forming the conductive layer CD (the step S306) and the step of disposing the first electrode E1 (the step S304) may be performed in any order or may be performed simultaneously, it is not limited in the present embodiment.

The manufacturing method M300 of the packaged semiconductor element PU of the present embodiment further includes the step S308: disposing a second electrode E2 on the second surface SR2 of each of the semiconductor elements SU. In detail, after the structure shown in the process (II) of FIG. 15 is formed, the structure may be transferred from the carrier CR to a carrier CR′. The carrier CR′ may include a base BS' and a material layer ML′. The features of the base BS' and the material layer ML′ may refer to the description of the base BS and the material layer ML above, but not limited thereto. Specifically, as shown in the process (III) of FIG. 15, after the structure shown in the process (II) of FIG. 15 is transferred to the carrier CR′, the structure may be disposed on the carrier CR′ in the way that the first electrode E1 (or the first surface SR1 of the semiconductor element SU) faces downward. In such condition, the second surface SR2 of the semiconductor element SU may face upward or be away from the carrier CR′. The material layer ML′ may contact the first electrode E1 and/or the conductive layer CD, but not limited thereto. After that, the second electrode E2 may be disposed on the second surface SR2. Specifically, the second electrode E2 may be disposed on the second surface SR2 of the semiconductor element SU, the fourth surface SR4 of the filling material layer FM and the conductive layer CD, and the second electrode E2 may contact the second semiconductor layer S2 and the conductive layer CD. In such condition, the second electrode E2 is electrically connected to the second semiconductor layer S2 and the conductive layer CD, or the second electrode E2 is electrically connected between the second semiconductor layer S2 and the conductive layer CD. For example, in the present embodiment, the second electrode E2 may be disposed entirely on the semiconductor element SU, the filling material layer FM and the conductive layer CD, but not limited thereto. In such condition, the outer edge of the second electrode E2 may for example be circular or approximately circular in the normal direction of the carrier CR′, depending on the shape of the filling material layer FM. Through the above-mentioned structural design, the second semiconductor layer S2 may be electrically connected to the conductive layer CD through the second electrode E2. In other words, the portion of the conductive layer CD extending on the third surface SR3 may serve as a bonding element of the second semiconductor layer S2, which is located at the same side as the bonding element (that is, the first electrode E1) of the first semiconductor layer S1. Therefore, it facilitates the bonding of the packaged semiconductor element PU on the target substrate when transferring the packaged semiconductor element PU to the target substrate in the subsequent process. The second electrode E2 may include any suitable transparent conductive material, such as indium tin oxide (ITO), indium zinc oxide (IZO) or indium gallium oxide (IGO), but not limited thereto. In some embodiments, the second electrode E2 may include thin metal or metal mesh. For example, a very thin metal layer (such as a magnesium layer or a silver layer) may be formed, or a metal mesh layer having light-transmitting openings may be formed through screen printing or other patterning processes, thereby forming the second electrode E2.

After the second electrode E2 is disposed, the manufacturing method M300 of the packaged semiconductor element PU of the present embodiment may further include disposing an auxiliary element AE, wherein the auxiliary element AE may be disposed on the second electrode E2 or disposed at a side of the second electrode E2 opposite to the semiconductor element SU, such that the second electrode E2 is located between the auxiliary element AE and the second semiconductor layer S2. After the auxiliary element AE is disposed, the packaged semiconductor element PU may be formed.

It should be noted that FIG. 15 just exemplary shows the manufacturing process of a packaged semiconductor element PU, and other semiconductor elements SU that are transferred to the carrier CR may be packaged in the same way to form the packaged semiconductor elements PU. In addition, the manufacturing method of the packaged semiconductor element PU of the present embodiment is not limited to the steps mentioned above, which may further include other suitable steps according to the structural design of the packaged semiconductor element PU.

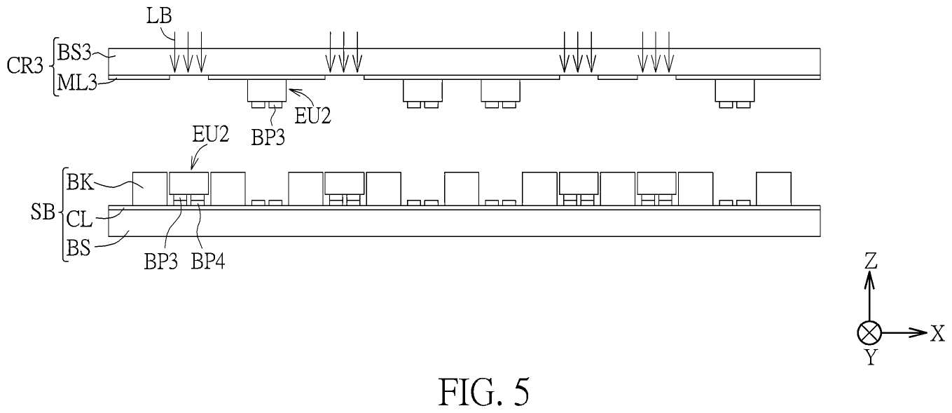

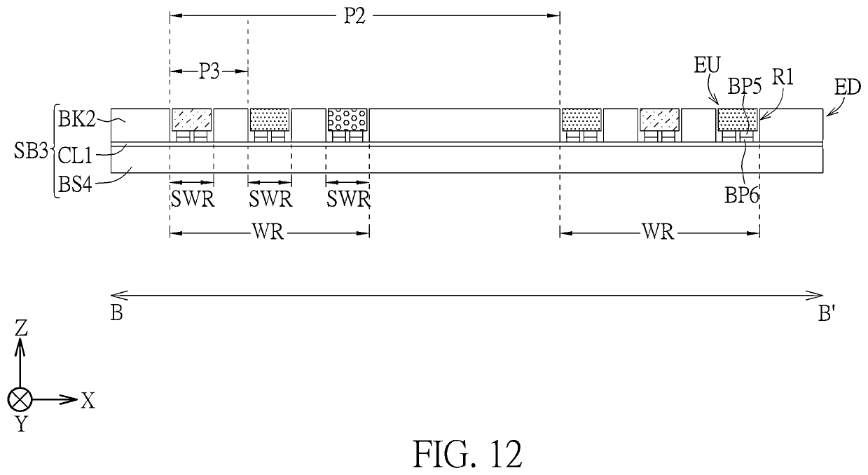

As shown in FIG. 16, the packaged semiconductor element PU of the present embodiment may include the semiconductor element SU, the filling material layer FM disposed to surround the sidewall SW of the semiconductor element SU, the first electrode E1 and the second electrode E2 respectively be disposed on the first surface SR1 and the second surface SR2 of the semiconductor element SU and the conductive layer CD disposed to surround the sidewall SW1 of the filling material layer FM, wherein the second electrode E2 contacts the conductive layer CD, such that the second semiconductor layer S2 is electrically connected to the conductive layer CD. The conductive layer CD may further extend on the third surface SR3 of the filling material layer FM in addition to being disposed to surround the sidewall SW1. In such condition, the packaged semiconductor element PU may have a vertical embedded flip chip structure. Specifically, the semiconductor element SU in the packaged semiconductor element PU may include a vertical type light emitting diode element and be embedded in the filling material layer FM, and when the packaged semiconductor element PU is transferred to the target substrate to form the electronic device in the subsequent process, the first semiconductor layer S1 and the second semiconductor layer S2 of the semiconductor element SU may be electrically connected to the bonding pads (such as the bonding pad BP4 shown in FIG. 5 or the bonding pad BP6 shown in FIG. 12) on the target substrate respectively through the first electrode E1 and the portion of the conductive layer CD located at the same side of the semiconductor element SU as the first electrode E1 (that is, the portion of the conductive layer CD extending on the third surface SR3), that is, the packaged semiconductor element PU may be bonded on the target substrate in a flip chip way.

In a cross-sectional view of the packaged semiconductor element PU (as shown in FIG. 16), the packaged semiconductor element PU has a first side F1 and a second side F2 opposite to the first side F1, wherein the first side F1 is defined as the side of the packaged semiconductor element PU where the first electrode E1 is located, and the second side F2 is defined as the side of the packaged semiconductor element PU where the second electrode E2 is located. According to the present embodiment, the first side F1 of the packaged semiconductor element PU may have a width W1, wherein the width W1 may range from 10 micrometers (μm) to 50 μm (that is, 10 μm≤W1≤50 μm), but not limited thereto. The width W1 may be defined as the maximum distance between two ends of the packaged semiconductor element PU at the first side F1 in a cross-sectional view of the packaged semiconductor element PU. For example, in the present embodiment, the width W1 may be the maximum distance between two ends of the conductive layer CD at the first side F1. In some embodiments, the width W1 may range from 15 μm to 45 μm (that is, 15 μm≤W1≤45 μm). In some embodiments, the width W1 may range from 20 μm to 40 μm (that is, 20 μm≤W1≤40 μm).

According to the present embodiment, in a cross-sectional view of the packaged semiconductor element PU (as shown in FIG. 16), the packaged semiconductor element PU may have a thickness TH1. The thickness TH1 may be defined as the maximum thickness of the packaged semiconductor element PU in the normal direction thereof. For example, the thickness TH1 may be defined as the maximum distance between the surface of the second electrode E2 opposite to the semiconductor element SU and the surface of the first electrode E1 (or the conductive layer CD) opposite to the semiconductor element SU in the normal direction of the packaged semiconductor element PU. According to the present embodiment, the thickness TH1 may range from 10 μm to 50 μm (that is, 10 μm≤TH1≤50 μm), but not limited thereto. In some embodiments, the thickness TH1 may range from 15 μm to 45 μm (that is, 15 μm≤TH1≤45 μm). In some embodiments, the thickness TH1 may range from 20 μm to 40 μm (that is, 20 μm≤TH1≤40 μm).

According to the present embodiment, an included angle θ1 may be between a portion of the conductive layer CD extending on the third surface SR3 and another portion of the conductive layer CD extending on the sidewall SW1. The included angle θ1 may also be regarded as the included angle between the third surface SR3 and the sidewall SW1. In other words, the value of the included angle θ1 may be determined by the shape design of the filling material layer FM. According to the present embodiment, the included angle θ1 may range from 90 degrees to 135 degrees (that is, 90°≤01≤135°), but not limited thereto. When the included angle θ1 is 90 degrees, a portion of the conductive layer CD extending on the surface SR3 is perpendicular to another portion of the conductive layer CD extending on the sidewall SW1, or the third surface SR3 is perpendicular to the sidewall SW1. In some embodiments, the included angle θ1 may range from 95 degrees to 130 degrees (that is, 95°≤θ1≤130°). In some embodiments, the included angle θ1 may range from 100 degrees to 125 degrees (that is, 100°≤θ1≤125°). By making the value of the included angle θ1 located within the above-mentioned range, the light emitting effect of the packaged semiconductor element PU may be improved.

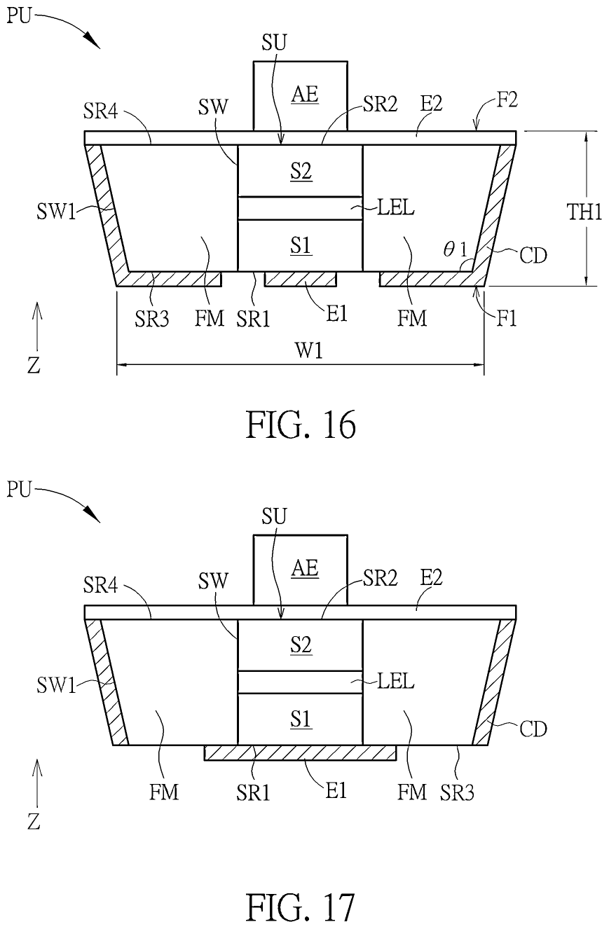

Referring to FIG. 17, FIG. 17 schematically illustrates a cross-sectional view of an electronic unit of an electronic device according to another embodiment of the present disclosure. One of the main differences between the packaged semiconductor element PU of the present embodiment and the packaged semiconductor element PU shown in FIG. 16 is the disposition position of the conductive layer CD. In detail, as shown in FIG. 17, the conductive layer CD of the packaged semiconductor element PU of the present embodiment may not be disposed on the third surface SR3 of the filling material layer FM or may not extend on the third surface SR3. Specifically, the conductive layer CD may extend on the sidewall SW1 of the filling material layer FM and be substantially aligned with the third surface SR3. In such condition, the packaged semiconductor element PU may have a vertical embedded chip structure. Specifically, the semiconductor element SU may include a vertical type light emitting diode element and be embedded in the filling material layer FM. In addition, in the present embodiment, the first electrode E1 of the packaged semiconductor element PU may further extend on the third surface SR3 of the filling material layer FM, that is, the first electrode E1 may simultaneously contact the first surface SR1 of the semiconductor element SU (or the first semiconductor layer S1) and the third surface SR3 of the filling material layer FM. It should be noted that although the conductive layer CD contacts the second electrode E2 in FIG. 17, it is not limited in the present embodiment. In some embodiments, the conductive layer CD may not contact the second electrode E2, and the second electrode E2 may be electrically connected to the bonding pads on the target substrate through other wires (not shown).

According to the present disclosure, after the packaged semiconductor element PU is formed through the manufacturing method M300 mentioned above, the packaged semiconductor element PU may be transferred to the target substrate through a fluid transfer process to form the electronic device. In other words, before performing the fluid transfer process on the semiconductor element SU, a packaging process may be performed on the semiconductor element SU. Since the semiconductor element SU of the present disclosure may include a vertical type light emitting diode element, the arrangement density of the semiconductor elements SU on the substrate (such as a wafer) may be increased, thereby improving utilization of the substrate. In addition, by performing a packaging process on the semiconductor element SU to form the packaged semiconductor element PU before the fluid transfer process of the semiconductor element SU, the bonding element (that is, the first electrode E1) of the first semiconductor layer S1 of the semiconductor element SU and the bonding element (that is, the portion of the conductive layer CD extending on the third surface SR3) of the second semiconductor layer S2 of the semiconductor element SU may be located at the same side of the packaged semiconductor element PU, which facilitates bonding of the packaged semiconductor element PU on the target substrate to form the electronic device. The steps of the fluid transfer process of the packaged semiconductor element PU will be detailed in the following. It should be noted that the electronic unit EU (including the electronic unit EUA, the electronic unit EUB, the electronic unit EUC, the first electronic unit EU and the second electronic unit EU2) mentioned in the following may be any one of the packaged semiconductor element PU in the embodiments mentioned above. The structure of the electronic unit EU shown in the following figures is exemplary, and the detail of the structure of the electronic unit EU may refer to FIG. 16, FIG. 17 and related contents above.

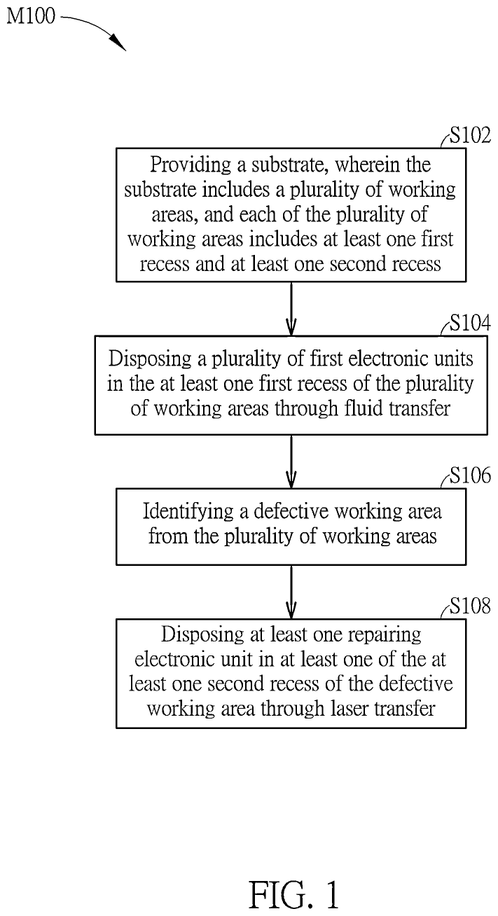

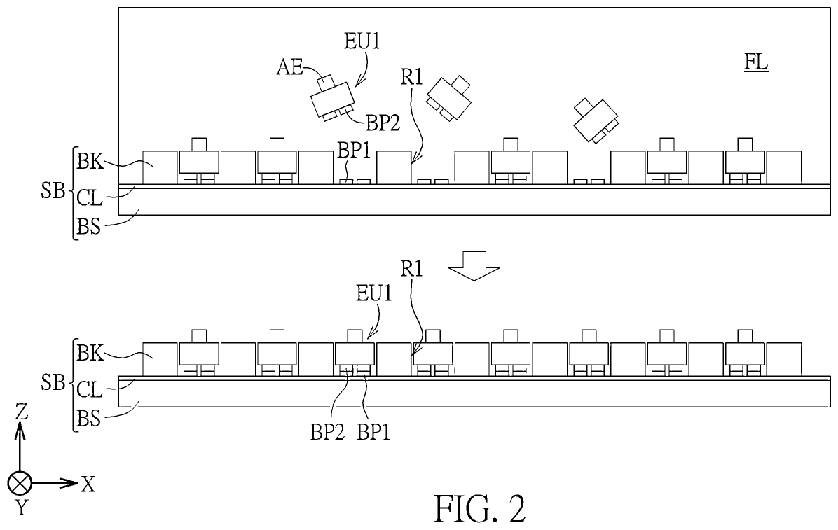

Referring to FIG. 1 to FIG. 6, FIG. 1 shows the flow chart of a manufacturing method of an electronic device according to a first embodiment off the present disclosure, and FIG. 2 to FIG. 6 schematically illustrate the manufacturing method of the electronic device of the present embodiment. Specifically, FIG. 2 to FIG. 6 show the transferring process of the packaged semiconductor elements PU. According to the present embodiment, the manufacturing method M100 of the electronic device ED (shown in FIG. 6) may include the following steps:
S102: providing a substrate, wherein the substrate includes a plurality of working areas, and each of the plurality of working areas includes at least one first recess and at least one second recess;
S104: disposing a plurality of first electronic units in the at least one first recess of the plurality of working areas through fluid transfer;
S106: identifying a defective working area from the plurality of working areas; and
S108: disposing at least one repairing electronic unit in at least one of the at least one second recess of the defective working area through laser transfer.

The details of the steps of the manufacturing method M100 of the electronic device ED will be described in the following.

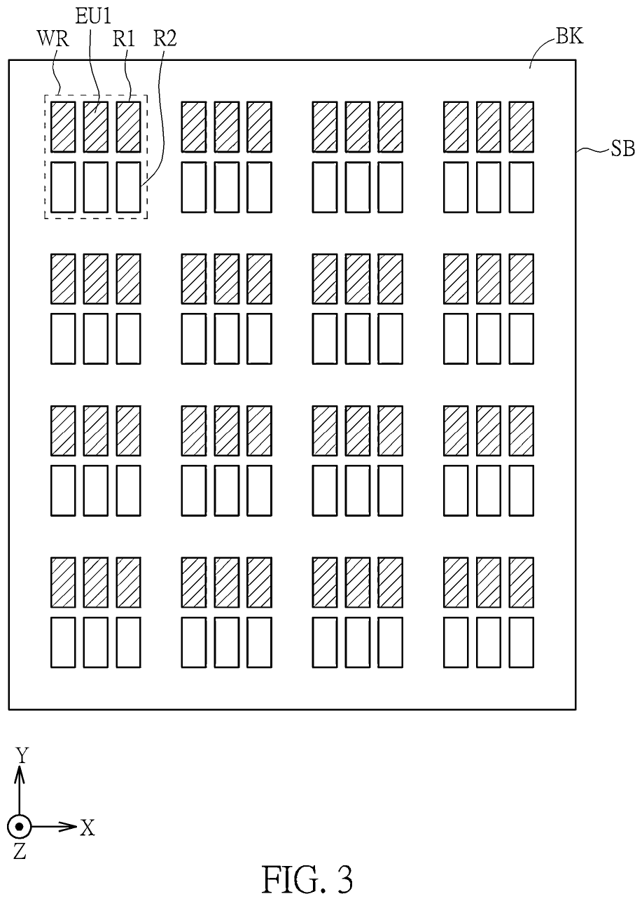

Referring to FIG. 2 and FIG. 3, FIG. 2 schematically illustrates the fluid transfer process according to the first embodiment of the present disclosure, and FIG. 3 schematically illustrates top views of a substrate and electronic units according to the first embodiment of the present disclosure. In the present embodiment, the manufacturing method M100 of the electronic device ED may include the step S102: providing a substrate SB at first. The substrate SB may include a plurality of working areas WR, and each of the working areas WR may include at least one first recess R1 and at least one second recess R2. As shown in FIG. 2 and FIG. 3, the substrate SB may include a base BS and a circuit layer CL disposed on the base BS. The base BS may include a rigid base or a flexible base. The rigid base for example includes glass, quartz, sapphire, ceramic, other suitable materials or combinations of the above-mentioned materials, but not limited thereto. The flexible base for example includes polyimide (PI), polycarbonate (PC), polyethylene terephthalate (PET), other suitable materials or combinations of the above-mentioned materials, but not limited thereto. The circuit layer CL may include various kinds of wires, circuits, electronic units (such as active elements and/or passive elements) that can be applied to the electronic device ED, but not limited thereto. For example, the circuit layer CL may include driving units, wherein the driving units may be electrically connected to the electronic units disposed in the subsequent process, thereby driving the electronic units, but not limited thereto. The circuit layer CL may include thin film transistor (TFT) elements, that is, may include elements and/or layers such as semiconductor layers, gate electrodes, source electrodes and drain electrodes, but not limited thereto. The semiconductor layer may include silicon or metal oxides, such as low temperature polysilicon (LTPS) semiconductor, amorphous silicon (a-Si) semiconductor or metal oxide semiconductor. The metal oxide semiconductor may for example include indium gallium zinc oxide (IGZO) semiconductor, but not limited thereto. It should be noted that the circuit layer CL may include any suitable element according to the usage or type of the electronic device ED, which is not limited to the above-mentioned contents. In the present embodiment, the substrate SB may be a complementary metal oxide semiconductor (CMOS) substrate or a thin film transistor substrate, but not limited thereto.

In the present embodiment, the working areas WR on the substrate SB may be arranged in an array, but the present disclosure is not limited thereto. The working areas WR may include at least one first recess R1 and at least one second recess R2. For example, as shown in FIG. 3, each of the working areas WR may include three first recesses R1 and three second recesses R2, wherein the first recesses R1 may be arranged along a direction (for example, the direction X), the second recesses R2 may be arranged along the same direction, and a second recess R2 may be adjacent to a first recess R1 (for example, a second recess R2 and a first recess R1 may correspond to each other), but not limited thereto. It should be noted that in other embodiments, the numbers and arrangements of the first recesses R1 and the second recesses R2 in the working areas WR may be adjusted according to the design of the electronic device ED, and is not limited to what is shown in FIG. 3. Specifically, the substrate SB may further include a bank structure BK disposed on the circuit layer CL. The bank structure BK may be disposed on a side of the circuit layer CL opposite to the base BS. The first recesses R1 and the second recesses R2 may be defined by the bank structure BK. In detail, the bank structure BK may include a plurality of openings, and the openings may form the first recesses R1 and the second recesses R2. That is, the first recesses R1 and the second recesses R2 may be enclosed by the bank structure BK. The bank structure BK may include any suitable insulating material. According to the present embodiment, in the subsequent process, the electronic units will be disposed in the working areas WR of the substrate SB, for example, the electronic units will be disposed in the first recesses R1 of the working areas WR.

After the substrate SB is provided, the step S104 may be performed to dispose a plurality of first electronic units EU1 in the at least one first recess R1 of the plurality of working areas WR through fluid transfer. Specifically, a carrier (not shown) may be provided at first, wherein the first electronic units EU1 are disposed on the carrier. The carrier mentioned here may include wafer or other suitable base that is suitable to support the first electronic units EU1. After that, the first electronic units EU1 on the carrier may be transferred to the substrate SB through a fluid transfer process, such that the first electronic units EU1 are disposed in the first recesses R1 of the working areas WR. In detail, as shown in the upper part of FIG. 2, the first electronic units EU1 may be transferred from the carrier to the substrate SB through a fluid FL and enter the first recesses R1, wherein the first electronic units EU1 may be electrically connected to the circuit layer CL. Specifically, the circuit layer CL may include a plurality of bonding pads BP1 which are exposed by the first recess R1, and the bonding pads BP2 of the first electronic units EU1 may contact the bonding pads BP1 of the circuit layer CL when the first electronic units EU1 enter the first recesses R1, thereby electrically connecting the first electronic units EU1 to the circuit layer CL. In the present embodiment, the bonding pads BP1 and the bonding pads BP2 may be bonded to each other by any suitable process, such as eutectic bonding, conductive film bonding, metal bonding, conductive paste bonding or other suitable processes. Therefore, the operation of the first electronic units EU1 may be controlled through the circuit layer CL. It should be noted that the positions of the bonding pads shown in FIG. 2 and following figures are exemplary. The positions of the bonding pads (or bonding elements) of the electronic units EU (that is, the packaged semiconductor elements PU) may refer to the structures shown in FIG. 16, FIG. 17 and related contents mentioned above, and the positions of the bonding pads of the circuit layer CL may correspond to the positions of the bonding pads of the electronic units EU. The first electronic unit EU1 may include an auxiliary element AE, wherein the auxiliary element AE may be a column structure disposed at a side of the first electronic unit EU1 opposite to the bonding pads BP2, but not limited thereto. In the transferring process of the first electronic units EU1, the auxiliary element AE may help to make the bonding pads BP2 of the first electronic unit EU1 face down, or face the substrate SB, such that the bonding pads BP2 may contact the bonding pads BP1. After the transfer process of the first electronic units EU1 is finished, as shown in the lower part of FIG. 2 or FIG. 3, the first electronic units EU1 would be disposed in the first recesses R1 and be electrically connected to the circuit layer CL, and the second recesses R2 may be vacant, or the first electronic unit EU1 is not disposed in the second recesses R2. After that, the auxiliary element AE may be removed.

In the present embodiment, the first electronic units EU1 may be disposed in the first recesses R1 through the fluid transfer process, but not disposed in the second recesses R2. Specifically, the effect of making the first electronic units EU1 disposed in the first recesses R1 but not disposed in the second recesses R2 may be achieved by making the shapes or sizes of the first recess R1 and the second recess R2 be different or by making the shape or the size of the first electronic unit EU1 match the shape or the size of the first recess R1. In some embodiments, although it is not shown in the figure, the second recess R2 and the first recess R1 may include the same shape, and the size of the first recess R1 may be greater than the size of the second recess R2. “The sizes of the first recess R1 and the second recess R2” described herein may be the areas of the first recess R1 and the second recess R2 in a top view (for example, viewed in a direction parallel to the direction Z) of the substrate SB or the volumes of the first recess R1 and the second recess R2, but not limited thereto. The definition of “size” mentioned in the following may refer to the contents mentioned above, and will not be redundantly described. In addition, the size of the first electronic unit EU1 may be lower than or equal to the size of the first recess R1 but greater than the size of the second recess R2. Therefore, the first electronic unit EU1 may not be disposed in the second recess R2. In some embodiment, although it is not shown in the figure, the shape of the first recess R1 may be different from the shape of the second recess R2, wherein the shape of the first electronic unit EU1 may match the shape of the first recess R1 but not match the shape of the second recess R2, such that the first electronic unit EU1 may be disposed in the first recess R1 but not be disposed in the second recess R2. For example, in the top view of the substrate SB, the first recess R1 and the first electronic unit EU1 may have a circular outline, and the second recess R2 may have a rectangular outline, but not limited thereto. It should be noted that the shape or size of the first electronic unit EU1 mentioned above may be determined according to the design of shape or size of the filling material layer FM of the packaged semiconductor element PU.

In some embodiments, the electronic device ED may include a sensing device. In such condition, the first electronic units EU1 (or the semiconductor elements SU) may include any suitable sensing units, such as photodiode, but not limited thereto. In some embodiments, the electronic device ED may include a display device. In such condition, the first electronic units EU1 (or the semiconductor elements SU) may include light emitting units, such as light emitting diodes, but not limited thereto. The light emitting diode may for example include organic light emitting diode (OLED), quantum light-emitting diode (QLED), inorganic light emitting diode (LED), other suitable light emitting elements or combinations of the above-mentioned elements. The inorganic light emitting diode may for example include mini light emitting diode (mini LED) or micro light emitting diode (micro LED), but not limited thereto. In some embodiments, the chip size of the light emitting diode may be about 300 micrometers (μm) to 10 millimeters (mm), the chip size of the mini light emitting diode may be about 100 μm to 300 μm, and the chip size of the micro light emitting diode may be about 1 μm to 100 μm, but not limited thereto. In some embodiments, the electronic device ED may include a self-emissive display device. In such condition, the electronic device ED may include a display medium layer, wherein the display medium layer may include light emitting diodes, but not limited thereto. In some embodiments, the electronic device ED may include non-self-emissive display device. In such condition, the electronic device ED may include a display medium layer, wherein the display medium layer may include liquid crystal, but not limited thereto. The display device is taken as an example of the electronic device ED to describe the examples of the transfer process of the first electronic units EU1 of the present embodiment.

In some embodiments, the first electronic units EU1 may include light emitting units that emit lights of the same color or wavelength, such as blue light emitting units, but not limited thereto. In such condition, the first electronic units EU1 may be transferred onto the substrate SB and be disposed in the first recesses R1 through the fluid transfer process, thereby forming the structure shown in FIG. 3. After that, a light converting layer may be disposed on the substrate SB to convert the color or wavelength of the lights emitted by the first electronic units EU1. For example, the first electronic units EU1 may be the optical units capable of emitting blue lights, and the lights emitted by a portion of the first electronic units EU1 may be converted into a green light or a red light through the light converting layer, but not limited thereto. The light converting layer may be disposed corresponding to the first electronic units EU1 or disposed corresponding to the first recesses R1 and/or the second recesses R2. In some embodiments, after the light converting layer is disposed, each of the working areas WR may include three first recesses R1, one of the three first recesses R1 corresponds to the light converting layer capable of converting the light into red light, another one of the three first recesses R1 corresponds to the light converting layer capable of converting the light into green light, and the other one of the three first recesses R1 may not correspond to the light converting layer, such that the first electronic units EU1 in the three first recesses R1 may respectively emit red light, green light and blue light, which can be mixed into a white light. In such condition, a working area WR may be regarded as a pixel, and the three first recesses R1 in the working area WR may respectively be regarded as a sub-pixel, but not limited thereto. It should be noted that the type or disposition of the light converting layer mentioned above are just exemplary, and the present disclosure is not limited thereto.

In some embodiments, the first electronic units EU1 may include light emitting units emitting lights of different colors or wavelengths. For example, the first electronic units EU1 may include blue light emitting units, green light emitting units and red light emitting units, wherein a blue light emitting unit, a green light emitting unit and a red light emitting unit may together to be regarded as a pixel, but not limited thereto. In some embodiments, each of the working areas WR may include three first recesses R1, and the three first recesses R1 may respectively include a blue light emitting unit, a green light emitting unit and a red light emitting unit. In such condition, the blue light emitting units, the green light emitting units and the red light emitting units may respectively be transferred into the first recesses R1 of the substrate SB through three processes. In some embodiments, the three first recesses R1 of each of the working areas WR may respectively have a first size, a second size and a third size, wherein the first size may be greater than the second size, and the second size may be greater than the third size. In the transfer process of the first electronic units EU1, a type of the light emitting units with the greatest size among the blue light emitting units, the green light emitting units and the red light emitting units may be transferred at first, wherein the size of the type of the light emitting units may be lower than or equal to the first size and greater than the second size and the third size, such that the type of the light emitting units may enter the first recesses R1 with the first size but not enter the first recesses R1 with the second size and the third size. After that, a type of the light emitting units with the second greatest size among the blue light emitting units, the green light emitting units and the red light emitting units may be transferred, wherein the size of the type of the light emitting units may be lower than or equal to the second size and greater than the third size, such that the type of the light emitting units may enter the first recesses R1 with the second size but not enter the first recesses R1 with the third size. After that, a type of the light emitting units with the lowest size among the blue light emitting units, the green light emitting units and the red light emitting units may be transferred, wherein the size of the type of the light emitting units may be lower than or equal to the third size, such that the type of the light emitting units may enter the first recesses R1 with the third size. Through the above-mentioned design, the blue light emitting units, the green light emitting units and the red light emitting units may be disposed in the first recesses R1 through multiple fluid transfer processes, and the three first recesses R1 of each of the working areas WR may respectively include a blue light emitting unit, a green light emitting unit and a red light emitting unit. It should be noted that the design of the first recesses R1 is not limited to the contents mentioned above. In some embodiments, the three first recesses R1 of each of the working areas WR may respectively have different shapes, and the blue light emitting units, the green light emitting units and the red light emitting units may have the shapes respectively match or corresponding the shape of one of the three first recesses R1, the shape of another one of the three first recesses R1 and the shape of the other one of the three first recesses R1, such that the light emitting units of different colors may be disposed in the first recesses R1 with the corresponding shapes. It should be noted that the above-mentioned fluid transfer process of the first electronic units EU1 may be applied to any suitable embodiments in which the first electronic units EU1 includes different types of electronic elements.

It should be noted that the working area WR may include any number of first recesses R1 and second recesses R2 according to the design or use of the electronic device ED, and the first recesses R1 and the second recesses R2 may be arranged in any way.

After the first electronic units EU1 are transferred into the first recesses R1 through the fluid transfer process, the step S106 may be performed to identify a defective working area from the plurality of working areas. Specifically, an inspection step may be performed on the first electronic units EU1 in the first recesses R1 to find a defective first electronic unit or the first recess R1 in which the first electronic unit EU1 is not disposed. When the defective first electronic unit or no first electronic unit EU1 is included in the first recess R1 of a working area WR, the working area WR may be defined as the defective working area. In other words, the defective first electronic unit or no first electronic unit EU1 is disposed in at least one of the first recess R1 of the defective working area. The inspection step of the first electronic units EU1 may be performed through any suitable way, such as photoluminescence or electroluminescence, but not limited thereto. FIG. 6 schematically illustrates top views of the substrate and the electronic units after the repairing process according to the first embodiment of the present disclosure. For example, as shown in FIG. 6, after the inspection step of the first electronic units EU1, four defective first electronic units DEU1 may be detected, and the working areas WR where the four defective first electronic units DEU1 are located may be defined as the defective working areas DWR. Although it is not shown in FIG. 6, in some embodiments, when at least one first recess R1 of a working area WR is vacant, the working area WR may also be regarded as the defective working areas DWR.

After the defective working area(s) DWR is identified, the step S108 may be performed to dispose at least one repairing electronic unit in at least one of the at least one second recess of the defective working area through laser transfer. Specifically, as shown in FIG. 6, after the defective working area(s) DWR is identified, the repairing electronic unit(s) REU may be transferred into at least one of the second recesses R2 of the defective working area(s) DWR through a laser transfer. In the present embodiment, each of the second recesses R2 of a working area WR may be disposed adjacent to a first recess R1 of the working area WR, but not limited thereto. In such condition, when the repairing electronic unit(s) REU is disposed, the repairing electronic unit(s) REU may be disposed in the second recess R2 adjacent to the first recess R1 in which the defective first electronic unit DEU1 is disposed, but not limited thereto. For example, as shown in FIG. 6, in a defective working area DWR, when the defective first electronic unit DEU1 is disposed in the middle first recess R1, the repairing electronic unit REU may be disposed in the middle second recess R2 of the defective working area DWR. In some embodiments, the repairing electronic unit REU may be disposed in the second recess R2 adjacent to the first recess R1 in which no first electronic unit EU1 is disposed. In some embodiments, when a defective working area DWR includes a plurality of first recesses R1 in which the defective first electronic units DEU1 are disposed, the repairing electronic units REU may respectively be disposed in the second recesses R2 adjacent to the plurality of first recesses R1. It should be noted that the above-mentioned description of the disposition position of the repairing electronic units REU is exemplary, and the present disclosure is not limited thereto. Optionally, when the defective first electronic unit DEU1 is disposed in the first recess R1, the electrical connection between the defective first electronic unit DEU1 and the driving unit may be cut off before or after the step S108 is performed. The method of cutting off the electrical connection may include laser cutting or other suitable ways, and the present disclosure is not limited thereto. In some embodiments, the repairing electronic unit REU may include the packaged semiconductor element PU. That is, the packaging process may be performed on the semiconductor element SU at first, and then the repairing process may be performed. In some embodiments, the repairing electronic unit REU may include the semiconductor element SU, that is, the packaging process may not be performed on the semiconductor element SU before the repairing process.

The variant embodiments of the present embodiment about transferring the repairing electronic units through laser transfer will be detailed in the following.

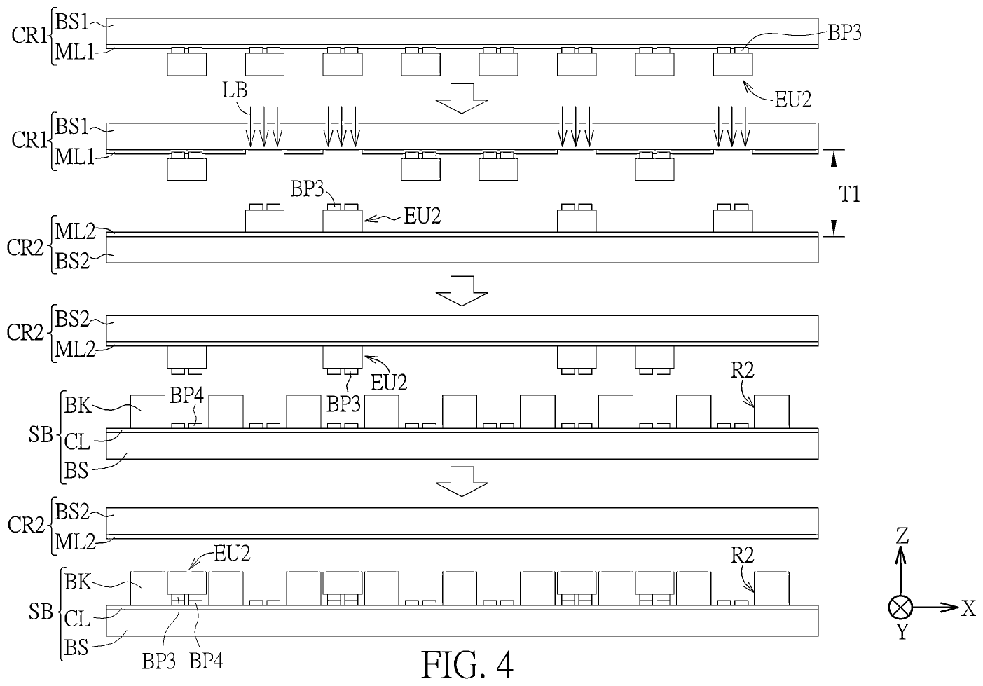

Referring to FIG. 4, FIG. 4 schematically illustrates disposition of repairing electronic units according to the first embodiment of the present disclosure. In some embodiments, the above-mentioned step of disposing the repairing electronic unit(s) REU in at least one of the second recesses R2 of the defective working area through laser transfer may include providing a first carrier CR1 at first, wherein the first carrier CR1 may include a plurality of second electronic units EU2. Specifically, the first carrier CR1 may include a base BS1 and a first material layer ML1 disposed on the base BS1, wherein the second electronic units EU2 may be adhered to the base BS1 through the first material layer ML1. In the present embodiment, the second electronic units EU2 may be disposed on the first carrier CR1 in the way that the bonding pads BP3 of the second electronic units EU2 face the first material layer ML1. The material of the base BS1 may refer to the material of the base BS mentioned above, but not limited thereto. The first material layer ML1 may include any suitable material that can react with laser light, such as the organic materials that can react with laser light, but not limited thereto. The above-mentioned “the first material layer ML1 may react with laser light” may include the situations that the first material layer ML1 is vaporized, peeled from the base BS1, disappeared, or generates gas after being irradiated with laser light, but not limited thereto.

After that, at least one of the second electronic units EU2 may be irradiated with the laser light LB, such that the at least one of the second electronic units EU2 may be transferred from the first carrier CR1 to a second carrier CR2. The second carrier CR2 may include a base BS2 and a second material layer ML2 disposed on the base BS2. The material of the base BS2 may refer to the material of the base BS mentioned above, but not limited thereto. The second material layer ML2 may include any suitable material having temporary adhesion to the second electronic units EU2. For example, the second material layer ML2 may include silicone, acrylic, resin, photo resin or other suitable materials. Specifically, the first carrier CR1 may be located above the second carrier CR2, wherein the first material layer ML1 of the first carrier CR1 and the second material layer ML2 of the second carrier CR2 may face each other. After that, a portion of the second electronic units EU2 may be irradiated with the laser light LB, wherein the portion of the first material layer ML1 corresponding to the portion of the second electronic units EU2 may react with the laser light LB and be disappeared, vaporized or may generate gas, such that the portion of the second electronic units EU2 may be peeled from the first carrier CR1 and fall on the second carrier CR2. Therefore, the second electronic units EU2 may be adhered to the base BS2 through the second material layer ML2, or it can be said that the second electronic units EU2 may be transferred to the second carrier CR2. In such condition, the bonding pads BP3 of the second electronic units EU2 may face upward, or the bonding pads BP3 may be away from the second material layer ML2. In the present embodiment, when the second electronic units EU2 are being transferred from the first carrier CR1 to the second carrier CR2, a distance T1 may be included between the base BS1 of the first carrier CR1 and the base BS2 of the second carrier CR2. According to the present embodiment, the distance T1 may range from 1 micrometer (μm) to 200 μm, but not limited thereto. By making the distance T1 located within the above-mentioned range, the possibility of damage of the second electronic units EU2 during the manufacturing process may be reduced.

After the portion of the second electronic units EU2 are transferred to the second carrier CR2, the portion of the second electronic units EU2 may be transferred from the second carrier CR2 to at least one second recesses R2 of the defective working area(s) DWR of the substrate SB. Specifically, the second carrier CR2 may be located above the substrate SB, wherein the second electronic units EU2 on the second carrier CR2 may correspond to the second recesses R2 where the repairing electronic units REU are expected to be disposed. The second carrier CR2 may be placed in the way that the second material layer ML2 faces the substrate SB, such that the bonding pads BP3 of the second electronic units EU2 face the second recesses R2. After that, the second carrier CR2 may move toward the substrate SB, such that the bonding pads BP3 of the second electronic units EU2 contact the bonding pads BP4 of the circuit layer CL of the substrate SB, thereby electrically connecting the second electronic units EU2 to the circuit layer CL. The bonding pads BP4 of the circuit layer CL may be disposed corresponding to the second recesses R2 and may be exposed by the second recesses R2. In the present embodiment, the bonding pads BP3 and the bonding pads BP4 may be bonded to each other through any suitable process, such as eutectic bonding, conductive film bonding, metal-metal bonding, conductive paste bonding or other suitable processes. After the bonding pads BP3 are bonded to the bonding pads BP4, the second carrier CR2 may be removed, and the second electronic units EU2 transferred to the second recesses R2 may serve as the repairing electronic units REU. Therefore, the process of transferring the repairing electronic units REU may be completed.

In the present embodiment, when the second electronic units EU2 are being transferred from the first carrier CR1 to the second carrier CR2, the irradiation position of the laser light LB on the first carrier CR1, or the second electronic units EU2 being irradiated with the laser light LB may be determined according to the positions of the first recesses R1 in which the defective first electronic unit DEU1 or no first electronic unit EU1 is disposed. In detail, the positions of the first recesses R1 in which the defective first electronic unit DEU1 is disposed or the vacant first recesses R1 of the defective working areas DWR may be confirmed at first, and the positions of the second recesses R2 where the repairing electronic units REU are expected to be disposed may thereby be determined. After that, the portion of the second electronic units EU2 being irradiated with the laser light LB may be determined according to the positions of those determined second recesses R2. Through the above-mentioned design, the second electronic units EU2 located on the second carrier CR2 may correspond to the positions of the second recesses R2 where the repairing electronic units REU are expected to be disposed. That is, the transfer process of the repairing electronic units REU may be completed at once.

Referring to FIG. 5, FIG. 5 schematically illustrates disposition of repairing electronic units according to a variant embodiment of the first embodiment of the present disclosure. In some embodiments, the step of disposing the repairing electronic unit(s) REU in at least one of the second recesses R2 of the defective working area through laser transfer may include providing a carrier CR3 at first, wherein the carrier CR3 may include the plurality of second electronic units EU2. The carrier CR3 may include a base BS3 and a third material layer ML3 disposed on the base BS3, wherein the second electronic units EU2 may be adhered to the base BS3 through the third material layer ML3. In the present embodiment, the second electronic units EU2 may be disposed on the carrier CR3 in the way that the bonding pads BP3 of the second electronic units EU2 are away from the third material layer ML3. The material of the base BS3 may refer to the material of the base BS mentioned above, but not limited thereto. The third material ML3 may include any suitable material that can react with laser light. The material of the third material layer ML3 may for example refer to the material of the first material layer ML1 mentioned above, but not limited thereto.

After that, a portion of the second electronic units EU2 may be irradiated with the laser light LB, such that the portion of the second electronic units EU2 may be transferred from the carrier CR3 to at least one of the second recesses R2 of the defective working areas DWR. Specifically, the carrier CR3 may be located above the substrate SB, wherein the material layer ML3 of the carrier CR3 may face the substrate SB, such that the bonding pads BP3 of the second electronic units EU2 may face the second recesses R2. After that, a portion of the second electronic units EU2 corresponding to the second recesses R2 where the repairing electronic units REU are expected to be disposed may be irradiated with the laser light LB, wherein the portion of the third material layer ML3 corresponding to the portion of the second electronic units EU2 may react with the laser light LB and be disappeared, vaporized or may generate gas, such that the portion of the second electronic units EU2 may be peeled from the carrier CR3 and fall into the second recesses R2 where the repairing electronic units REU are expected to be disposed, and the bonding pads BP3 of the second electronic units EU2 may contact the bonding pads BP4, thereby electrically connecting the second electronic units EU2 to the circuit layer CL. In the present embodiment, the bonding pads BP3 and the bonding pads BP4 may be bonded to each other through any suitable process, such as eutectic bonding, conductive film bonding, metal bonding, conductive paste bonding or other suitable processes. The second electronic units EU2 transferred to the second recesses R2 may serve as the repairing electronic units REU. Therefore, the transfer process of the repairing electronic units REU may be completed. According to the present embodiment, the positions of the second recesses R2 where the repairing electronic units REU are expected to be disposed may be determined at first, and then, the portion of the second electronic units EU2 being irradiated with the laser light LB or the irradiation positions of the laser light LB on the carrier CR3 may be determined according to the positions of those second recesses R2.

According to the present embodiment, the manufacturing method of the electronic device ED may include transferring the first electronic units EU1 onto the substrate SB through fluid transfer process at first. Therefore, the randomness of distribution of the first electronic units may be improved, or the waste of the first electronic units may be reduced. For example, in some embodiments, when the electronic device ED includes the display device, using the fluid transfer process to transfer the first electronic units EU1 may reduce the uneven brightness distribution of the electronic device ED. In addition, using the fluid transfer process to transfer the first electronic units EU1 may improve the proportion of the transferred first electronic units EU1, thereby reducing the production cost. In addition, after the first electronic units EU1 are transferred, the manufacturing method of the electronic device ED of the present embodiment may further include transferring the repairing electronic units through the laser transfer process. Through the above-mentioned manufacturing processes, the yield of the electronic device ED may be improved.

After the above-mentioned steps are performed, the electronic device ED may thereby be formed. In other words, the electronic device ED of the present embodiment may be formed by performing the manufacturing method M300 and the manufacturing method M100 in sequence. It should be noted that the elements and/or the layers included in the electronic device ED are not limited to the above-mentioned elements or layers. The electronic device ED may include other suitable elements and/or layers according to the type of the electronic device ED. In addition, other steps may be inserted between the steps in the manufacturing method M100 of the present embodiment according to the demands. In addition, any step in the manufacturing method M100 may be adjusted in order or deleted according to the demands.

The manufacturing method of the electronic device according to another embodiment of the present disclosure will be detailed in the following.

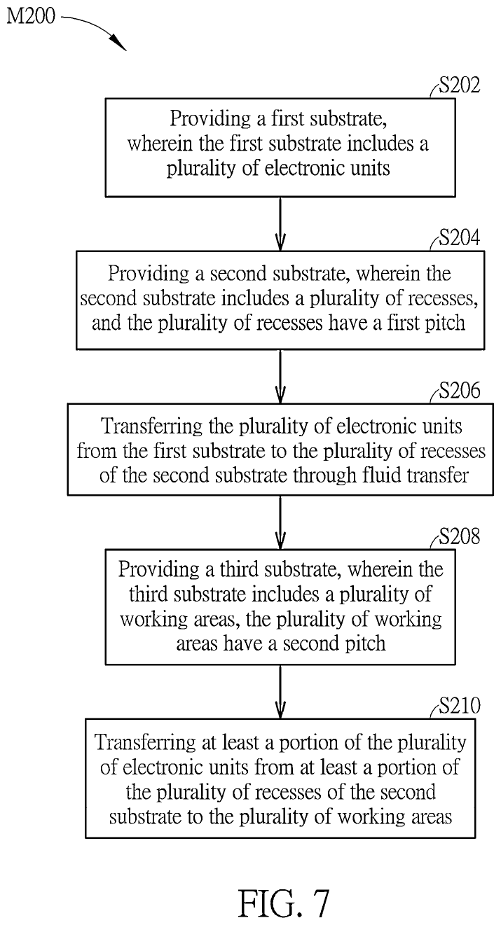

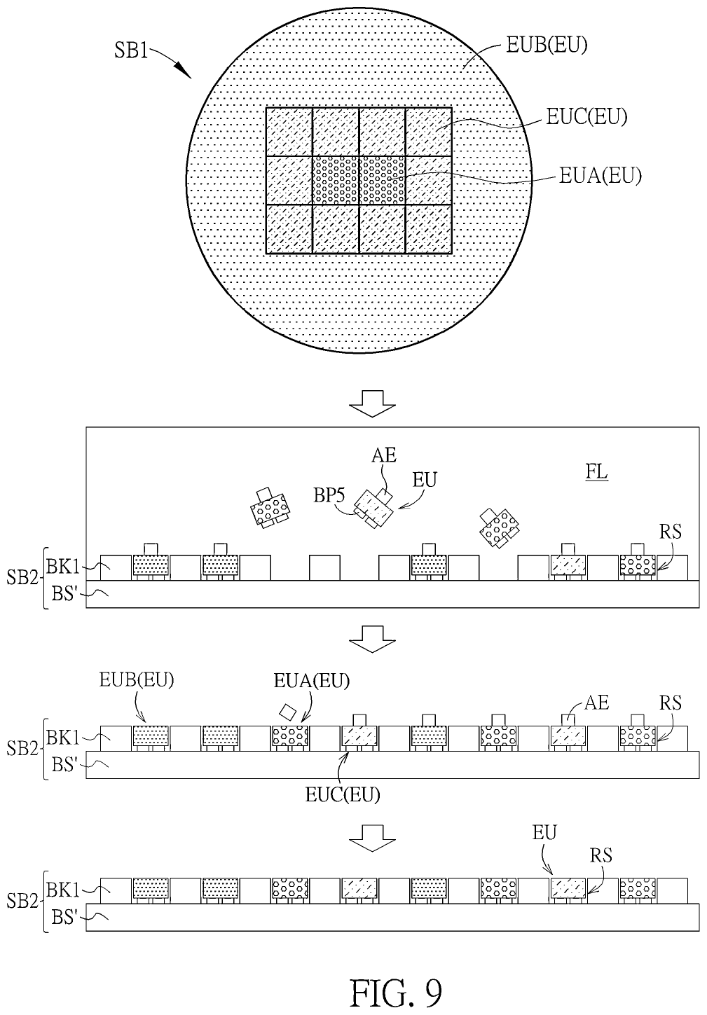

Referring to FIG. 7 and FIG. 9 to FIG. 13, FIG. 7 shows the flow chart of a manufacturing method of an electronic device according to a second embodiment of the present disclosure, and FIG. 9 to FIG. 13 schematically illustrate the manufacturing method of the electronic device of the present disclosure. Specifically, FIG. 9 to FIG. 1 show the transferring process of the packaged semiconductor elements PU. According to the present embodiment, the manufacturing method M200 of the electronic device ED may include the following steps:
S202: providing a first substrate, wherein the first substrate includes a plurality of electronic units;
S204: providing a second substrate, wherein the second substrate includes a plurality of recesses, and the plurality of recesses have a first pitch;
S206: transferring the plurality of electronic units from the first substrate to the plurality of recesses of the second substrate through fluid transfer;
S208: providing a third substrate, wherein the third substrate includes a plurality of working areas, the plurality of working areas have a second pitch; and
S210: transferring at least a portion of the plurality of electronic units from at least a portion of the plurality of recesses of the second substrate to the plurality of working areas.

The details of the steps of the manufacturing method M200 of the electronic device ED will be described in the following.

Referring to FIG. 9, FIG. 9 schematically illustrates the fluid transfer process according to the second embodiment of the present disclosure. In the present embodiment, the manufacturing method M200 of the electronic device ED may include the step S202: providing a first substrate SB1 at first, wherein the first substrate SB1 includes a plurality of electronic units EU. The first substrate SB1 may include any suitable base capable of carrying the electronic units EU, and the electronic units EU may be disposed on the first substrate SB1. The electronic units EU may be formed on the first substrate SB1, but not limited thereto. The first substrate SB1 may include any suitable shape. In the present embodiment, the first substrate SB1 may be circular, but not limited thereto. For example, the first substrate SB1 of the present embodiment may include a wafer, but not limited thereto. In some embodiments, the first substrate SB1 may for example be the carrier CR′ shown in FIG. 15, wherein the plurality of electronic units EU (that is, the packaged semiconductor elements PU) are disposed thereon.

After that, the step S204 may be performed to provide a second substrate SB2, wherein the second substrate SB2 includes a plurality of recesses RS. The structural features of the second substrate SB2 may refer to the structure of the substrate SB mentioned above, but not limited thereto. For example, the second substrate SB2 may include a base BS' and a bank structure BK1 disposed on the base BS′, wherein the base BS' may include a base and a circuit layer. In some embodiments, the base BS' may include the base but not include the circuit layer. The bank structure BK1 may define the recesses RS, that is, the recesses RS may be surrounded by the bank structure BK1. The second substrate SB2 may include any suitable shape. In the present embodiment, the second substrate SB2 may be rectangular, but not limited thereto.

It should be noted that the step S202 and the step S204 mentioned above may be performed in any order or performed simultaneously.

After that, the step S206 may be performed to transfer the plurality of electronic units EU from the first substrate SB1 to the plurality of recesses RS of the second substrate SB2 through fluid transfer. Specifically, the electronic units EU on the first substrate SB1 may be transferred to the second substrate SB2 through the fluid FL, wherein the electronic units EU may enter the recesses RS of the second substrate SB2, such that the electronic units EU are disposed in the recesses RS. In the present embodiment, the electronic units EU may completely occupy the recesses RS of the second substrate SB2, but not limited thereto. In the present embodiment, the electronic units EU may be transferred from a substrate with a shape to another substrate with another shape. For example, the electronic units EU may be transferred from a circular substrate (the first substrate SB1) to a rectangular substrate (the second substrate SB2), but not limited thereto. The electronic unit EU may include the auxiliary element AE, wherein the auxiliary element AE may help to make the bonding pads BP5 of the electronic unit EU face down, or face the second substrate SB2. After the transfer process of the electronic units EU, the auxiliary element AE may be removed, as shown in FIG. 9.

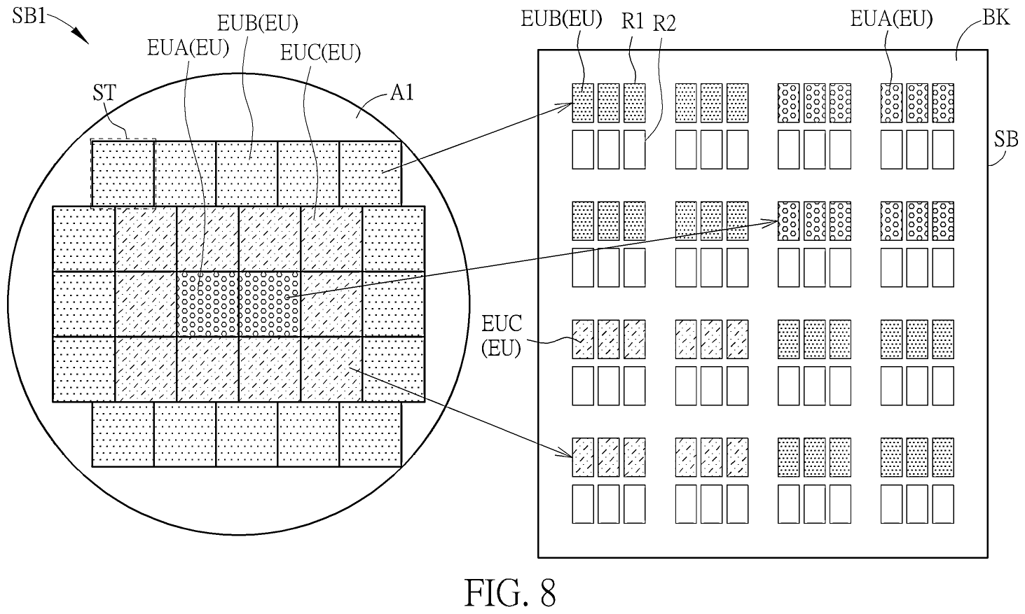

Referring to FIG. 8, FIG. 8 schematically illustrates the transfer of electronic units from a first substrate through stamp transfer. Specifically, if the stamp transfer is used to transfer the electronic units EU on the first substrate SB1, limited by the shape of the stamp tool, a portion of the electronic units EU on the first substrate SB1 may not be transferred through stamp transfer, such that the portion of the electronic units EU may be waste, thereby increasing production cost. For example, FIG. 8 shows the situation of transferring electronic units EU by using stamp transfer, wherein the stamp tool may pick up the electronic units EU in an area ST at a time, and the transfer process of the electronic units EU may be performed by multiple times of picking up. After the electronic units EU are picked up by the stamp tool, they can be transferred into the first recesses R1 of the substrate SB, and the details thereof may refer to the contents mentioned above, which will not be redundantly described. However, in such condition, a portion of the electronic units EU on the first substrate SB1 may not be picked up by the stamp tool. For example, the electronic units EU in the area A1 shown in FIG. 8 may not be transferred through stamp transfer process. Therefore, the electronic units EU in the area A1 may be waste, thereby increasing the production cost of the electronic device ED.

In addition, in some embodiments, the electronic units EU disposed on different areas of the first substrate SB1 may be the same type of electronic units EU, but the specific characteristic thereof may be different. The difference of the specific characteristic mentioned above may for example be caused by the manufacturing process of the electronic units EU, but not limited thereto. Specifically, the electronic units EU may include electronic units EUA, electronic units EUB and electronic units EUC which are disposed in different areas of the first substrate SB1, wherein the electronic units EUA, the electronic units EUB and the electronic units EUC may be the same type of electronic units, but the specific characteristics of the electronic units EUA, the electronic units EUB and the electronic units EUC may be different. For example, in some embodiments, the electronic units EU may include light emitting units, and the electronic units EUA, the electronic units EUB and the electronic units EUC may be the light emitting units of the same color, but the wavelengths of the lights respectively emitted by the electronic units EUA, the electronic units EUB and the electronic units EUC may be different. In such condition, transferring the electronic units EU by stamp transfer may cause insufficient randomness of distribution of the electronic units EUA, the electronic units EUB and the electronic units EUC which have different specific characteristics, thereby affecting the performance of the electronic device ED. For example, as shown in FIG. 8, after the electronic units EU are transferred to the substrate SB through stamp transfer, the electronic units EUA, the electronic units EUB and the electronic units EUC are not randomly arranged on the substrate SB. In such condition, when the electronic device ED includes the display device, the electronic device ED may have uneven brightness distribution, thereby affecting the display effect of the electronic device ED.

Return to FIG. 9, in another aspect, according to the present embodiment, since the electronic units EU on the first substrate SB1 may be transferred to the second substrate SB2 through the fluid transfer process, the electronic units EU may move into the recesses RS substantially through the fluid FL. Therefore, the waste of the electronic units EU may be reduced. In other words, in the present embodiment, the electronic units EU on a substrate with any shape may be transferred to another substrate while reducing the waste of the electronic units EU. In addition, after the electronic units EU are transferred into the recesses RS through the fluid FL, the electronic units EU in different areas of the first substrate SB1 (such as the electronic units EUA, the electronic units EUB and the electronic units EUC mentioned above) may be randomly arranged on the second substrate SB2, or may be randomly disposed in the recesses RS. Therefore, when the electronic units EU are transferred to the third substrate SB3 in the subsequent process, the electronic units EUA, the electronic units EUB and the electronic units EUC may be distributed randomly on the third substrate SB3 (as shown in FIG. 13), thereby reducing the influence of characteristic difference of the electronic units EUA, the electronic units EUB and the electronic units EUC on the performance of the electronic device ED. For example, when the electronic device ED includes the display device, the above-mentioned design may improve the brightness uniformity of the electronic device ED.

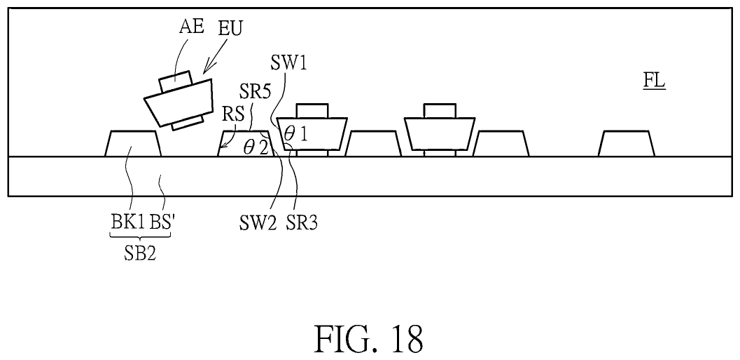

Referring to FIG. 18, FIG. 18 schematically illustrates the fluid transfer process according to a variant embodiment of the second embodiment of the present disclosure. In the present variant embodiment, the shape of the bank structure BK1 may be determined according to the shape of the electronic unit EU. Specifically, as shown above, the electronic unit EU may include the packaged semiconductor element PU, wherein the included angle θ1 is included between the third surface SR3 of the filling material layer FM (not shown) and the sidewall SW1 of the packaged semiconductor element PU. In such condition, the bank structure BK1 may have a surface SR5 away from the second substrate SB2 and a sidewall SW2, and in a cross-sectional view of the bank structure BK1, an included angle θ2 may be included between the surface SR5 of the bank structure BK1 and the sidewall SW2, wherein the included angle θ2 may substantially be the same as the included angle θ1, but not limited thereto. The range of the included angle θ2 may refer to the range of the included angle θ1 mentioned above. Through the shape design of the bank structure BK1 mentioned above, the possibility of flipping of the electronic unit EU during the transfer process may be reduced, thereby improving the yield of the manufacturing process.

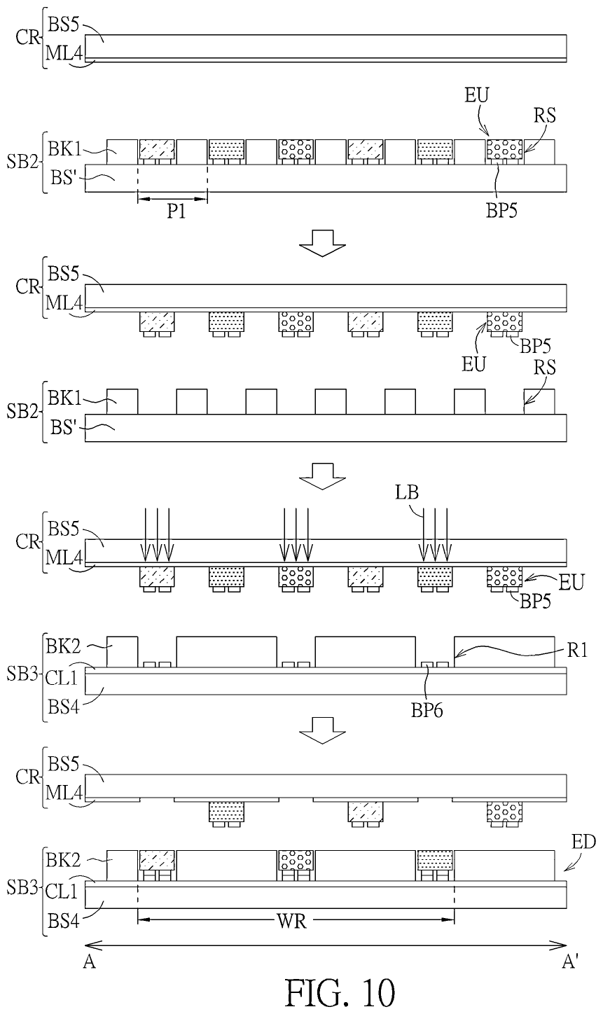

After the electronic units EU are moved into the recesses RS of the second substrate SB2, the step S208 may be performed to provide a third substrate SB3, wherein the third substrate SB3 includes a plurality of working areas WR. The structural features of the third substrate SB3 may refer to the structural features of the substrate SB mentioned above. For example, as shown in FIG. 10 to FIG. 12, the third substrate SB3 may include a base BS4, a circuit layer CL1 disposed on the base BS4 and a bank structure BK2 disposed on the circuit layer CL1, wherein the bank structure BK2 may define at least one first recess R1 and at least one second recess R2 (as shown in FIG. 13). The structural features of the base BS4, the circuit layer CL1 and the bank structure BK2 may respectively refer to the base BS, the circuit layer CL and the bank structure BK mentioned above. As shown in FIG. 13, the third substrate SB3 may include a plurality of working areas WR, wherein the working areas WR may be arranged in an array, but not limited thereto. Each of the working areas WR of the third substrate SB3 may include at least one first recess R1 and at least one second recess R2, but not limited thereto.

After that, the step S210 may be performed to transfer a portion of the plurality of electronic units EU from a portion of the plurality of recesses RS of the second substrate SB2 to the plurality of working areas WR. Specifically, a portion of the electronic units EU in the recesses RS of the second substrate SB2 may be transferred into the first recesses R1 of the working areas WR of the third substrate SB3, such that the electronic units EU may be disposed in the first recesses R1. The variant embodiments of the present embodiment about transferring the electronic units EU from the second substrate SB2 to the third substrate SB3 will be detailed in the following.

Referring to FIG. 10, FIG. 10 schematically illustrates transfer of the electronic units from a second substrate to a third substrate according to the second embodiment of the present disclosure. In some embodiments, the method of transferring the electronic units EU from the second substrate SB2 to the third substrate SB3 may include providing a carrier CR at first, wherein the carrier CR may include a base BS5 and a fourth material layer ML4 disposed on the base BS5. The material of the base BS5 may refer to the material of the base BS mentioned above, but not limited thereto. The fourth material layer ML4 may include any suitable material that can react with laser light. The material of the fourth material layer ML4 may for example refer to the material of the first material layer ML1 mentioned above, but not limited thereto.

After that, the plurality of electronic units EU may be transferred from the recesses RS to the carrier CR. Specifically, the carrier CR may move toward the second substrate SB2, such that the fourth material layer ML4 of the carrier CR contacts the electronic units EU disposed in the recesses RS (for example, the fourth material layer ML4 contacts the surface SR of the electronic unit EU opposite to the bonding pads BP5). Therefore, the electronic units EU may be adhered to the base BS5 through the fourth material layer ML4, such that the electronic units EU in the recesses RS are transferred to the carrier CR. In such condition, the bonding pads BP5 of the electronic unit EU may be located at a side of the electronic unit EU opposite to the fourth material layer ML4.

After that, a portion of the electronic units EU may be irradiated with the laser light LB, such that the portion of the electronic units EU may be transferred from the carrier CR to the third substrate SB3 or the working areas WR of the third substrate SB3. Specifically, a portion of the electronic units EU may be irradiated with the laser light LB, wherein the portion of the fourth material layer ML4 corresponding to the portion of the electronic units EU may react with the laser light LB and be disappeared, vaporized or may generate gas, such that the portion of the electronic units EU may be peeled from the carrier CR. In the present embodiment, the portion of the electronic units EU being irradiated with the laser light LB may correspond to the recesses (that is, the first recesses R1) of the third substrate SB3, such that the portion of the electronic units EU may enter the first recesses R1 of the third substrate SB3 after being peeled from the carrier CR, and the portion of the electronic units EU may thereby be disposed in the first recesses R1 of the working areas WR of the third substrate SB3. In such condition, the bonding pads BP5 of the electronic units EU facing toward the third substrate SB3 may contact the bonding pads BP6 of the circuit layer CL1 of the third substrate SB3 exposed by the first recesses R1, such that the electronic units EU may be electrically connected to the circuit layer CL1. After the electronic units EU are transferred to the third substrate SB3, the electronic device ED may be formed. It should be noted that the electronic device ED may further include other suitable elements and/or layers, which is not limited to the structure shown in FIG. 10.

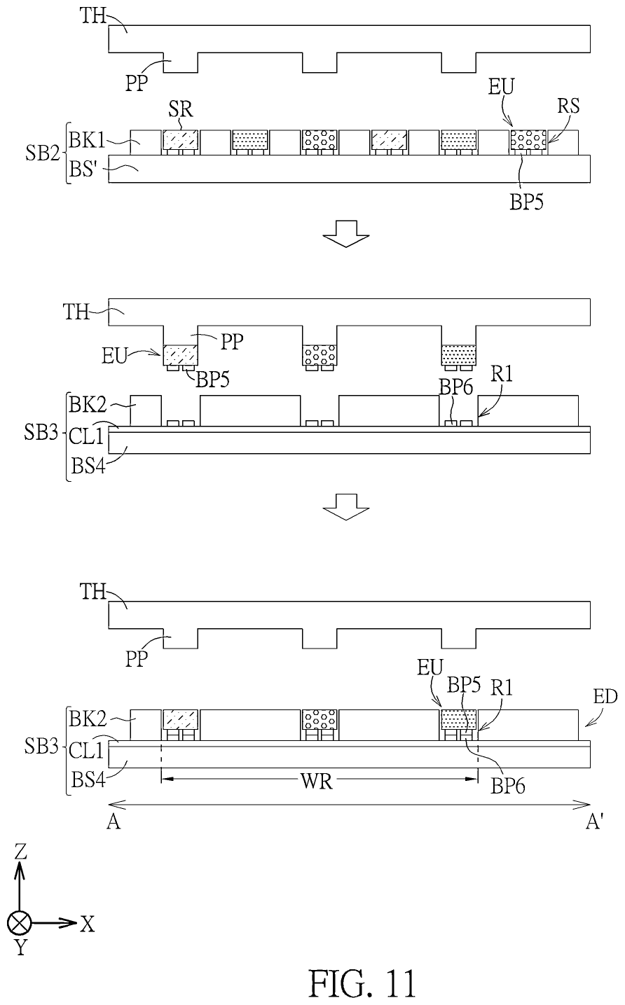

Referring to FIG. 11, FIG. 11 schematically illustrates transfer of the electronic units from the second substrate to the third substrate according to a variant embodiment of the second embodiment of the present disclosure. In some embodiments, the method of transferring the electronic units EU from the second substrate SB2 to the third substrate SB3 may include picking up a portion of the electronic units EU in a portion of the recesses RS at first. For example, a transfer head TH may be used to pick up a portion of the electronic units EU in a portion of the recesses RS of the second substrate SB2. Specifically, the transfer head TH may include a plurality of protruding structures PP, wherein the protruding structures PP may correspond to the electronic units EU which are expected to be picked up. After that, the transfer head TH may move toward the second substrate SB2, and each of the protruding structures PP may contact the surface SR of the electronic unit EU to which it correspond, thereby picking up the corresponding electronic unit EU. The pitch of the protruding structures PP may be determined according to the pitch of the first recesses R1 of the third substrate SB3, but not limited thereto. In addition, the structural design of the transfer head TH and the method of picking up the electronic units EU shown in FIG. 11 are just exemplary, and the present disclosure is not limited thereto.

After that, the portion of the electronic units EU being picked up by the transfer head TH may be transferred to the third substrate SB3 or the working areas WR of the third substrate SB3. Specifically, the protruding structures PP of the transfer head TH may be made to correspond to the first recesses R1 of the third substrate SB3 at first, and then, the transfer head TH may move toward the third substrate SB3, such that the electronic units EU may enter the first recesses R1, and the electronic units EU may thereby be disposed in the first recesses R1 of the working areas WR of the third substrate SB3. In such condition, the bonding pads BP5 of the electronic units EU facing toward the third substrate SB3 may contact the bonding pads BP6 of the circuit layer CL1 of the third substrate SB3, such that the electronic units EU may be electrically connected to the circuit layer CL1. After the electronic units EU are transferred to the third substrate SB3, the electronic device ED may be formed. It should be noted that the electronic device ED may further include other suitable elements and/or layers, which is not limited to the structure shown in FIG. 11.

It should be noted that after the electronic units EU are transferred to the working areas WR of the third substrate SB3, the inspection step of the electronic units EU and/or the step of disposing repairing electronic units EU may optionally be performed, and the details thereof may refer to the contents in the first embodiment mentioned above, which will not be redundantly described.

Referring to FIG. 10 to FIG. 12, FIG. 12 schematically illustrates a cross-sectional 1 view of the electronic device according to the second embodiment of the present disclosure. Specifically, the electronic devices ED shown in FIG. 10 and FIG. 11 may be the cross-sectional structure of the electronic device ED shown in FIG. 13 along a section line A-A′, and the electronic device ED shown in FIG. 12 may be the cross-sectional structure of the electronic device ED shown in FIG. 13 along a section line B-B′. According to the present embodiment, as mentioned above, when the electronic units EU are transferred from the second substrate SB2 to the third substrate SB3 to form the electronic device ED, only a portion of the electronic units EU on the second substrate SB2 are transferred, but not limited thereto. In other words, the electronic units EU of the electronic device ED may be a portion of the electronic units EU on the second substrate SB2. In such condition, the electronic units EU on the second substrate SB2 may be used in multiple transfer processes, or a single second substrate SB2 may be used to form a plurality of electronic devices ED. Specifically, the electronic units EU on the first substrate SB1 may be transferred to the second substrate SB2 through a fluid transfer process at first, and an arranging of the electronic units EU may be performed on the second substrate SB2. After that, a portion of the electronic units EU on the second substrate SB2 may be transferred (for example, through laser transfer or stamp transfer, but not limited thereto) to the working areas WR of the third substrate SB3. In some embodiments, in the second substrate SB2, a pitch may be included between the portion of the electronic units EU which are transferred, wherein the pitch may be determined according to the pitch of the first recesses R1 of the third substrate SB3, but not limited thereto. In such condition, the pitch of the recesses RS of the second substrate SB2 may be lower than the pitch of the working areas WR of the third substrate SB3. For example, as shown in FIG. 10 and FIG. 12, the recesses RS of the second substrate SB2 have a first pitch P1, and the working areas WR of the third substrate SB3 have a second pitch P2, wherein the second pitch P2 is greater than the first pitch P1. In the cross-sectional view of the second substrate SB2, the first pitch P1 may be defined as the distance between the edges at the same side of adjacent two recesses RS. For example, the first pitch P1 may be the distance between the left edges of adjacent two recesses RS, but not limited thereto. In the cross-sectional view of the third substrate SB3, the second pitch P2 may be defined as the distance between the edges at the same side of adjacent two working areas WR. For example, the second pitch P2 may be the distance between the left edges of adjacent two working areas WR, but not limited thereto. In the present embodiment, the first pitch P1 may be the pitch of adjacent two recesses RS in an arrangement direction of the recesses RS, and the second pitch P2 may be the pitch of adjacent two working areas WR in the same direction. For example, the first pitch P1 may be the pitch of adjacent two recesses RS in the direction X, and the second pitch P2 may be the pitch of adjacent two working areas WR in the direction X, but not limited thereto. In some embodiments, the first pitch P1 may be the pitch of adjacent two recesses RS in the direction Y, and the second pitch P2 may be the pitch of adjacent two working areas WR in the direction Y. In some embodiments, the second pitch P2 is an integer multiple of the first pitch P1 (that is, P2=n*P1, wherein n is a positive integer).

In some embodiments, as shown in FIG. 12, each of the working areas WR may include a plurality of sub working areas SWR, wherein a sub working area SWR may for example include a first recess R1 and/or a second recess R2 adjacent to the first recess R1. When the electronic device ED includes the display device, a sub working area SWR may be regarded as a sub-pixel, but not limited thereto. In such condition, the sub working areas SWR of a working area WR have a third pitch P3. In the cross-sectional view of the third substrate SB3, the third pitch P3 may be defined as the distance between the edges at the same side of adjacent two sub working areas SWR. For example, the third pitch P3 may be the distance between the left edges of adjacent two sub working areas SWR, but not limited thereto. The third pitch P3 may be defined in a direction which is the same as the first pitch P1 and the second pitch P2. For example, the first pitch P1 may be the pitch of adjacent two recesses RS in the direction X, and the third pitch P3 may be the pitch of adjacent two sub working areas SWR in the direction X. According to the present embodiment, the third pitch P3 is greater than the first pitch P1. In addition, in some embodiments, the third pitch P3 may be an integer multiple of the first pitch P1 (that is, P3=n*P1, wherein n is a positive integer).

It should be noted that the electronic device ED of the present embodiment may be transferred to the third substrate SB3 through one transfer process or multiple transfer processes, and the present disclosure is not limited thereto. In some embodiments, the electronic units EU may be transferred to the third substrate SB3 through one transfer process. In some embodiments, the electronic device ED may include different types of electronic elements (for example, the light emitting units of different colors which are mentioned above, but not limited thereto), and the electronic units EU may be transferred to the third substrate SB3 through multiple transfer processes, such that electronic elements of different types may respectively be transferred to the corresponding first recesses R1. Through the designs of the first pitch P1, the second pitch P2 and the third pitch P3 mentioned above, it is helpful to use a single second substrate SB2 for multiple transfer processes under the transfer process of various kinds of electronic units EU to form a plurality of electronic devices ED, thereby simplifying the manufacturing process of the electronic device ED or reducing the production cost of the electronic device ED.

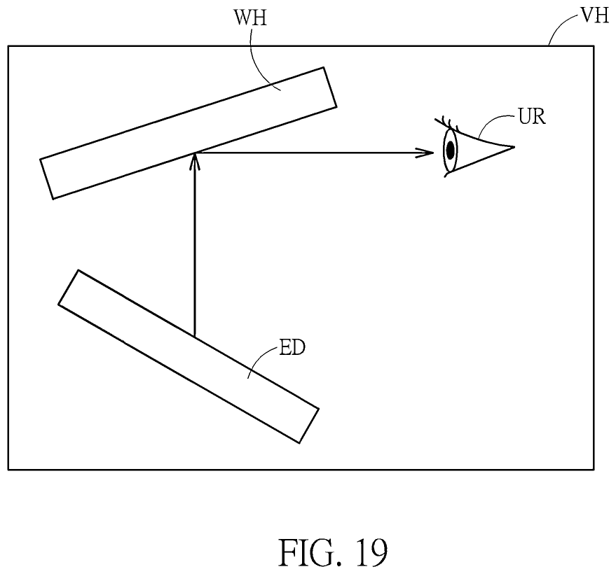

Referring to FIG. 19, FIG. 19 shows a schematic diagram of applying the electronic device of the present disclosure to a vehicle display. In detail, as shown in FIG. 19, the electronic device ED may be applied to a vehicle VH to serve as a vehicle display. Specifically, the light emitted by the electronic device ED may be reflected by a windshield WH and enter the eyes of the user UR, thereby being observed by the user. The electronic device ED shown in FIG. 19 may be the electronic device ED shown in FIG. 6 or the electronic device ED shown in FIG. 13. According to the present embodiment, since the electronic unit EU (not shown) in the electronic device ED includes the light emitting diode element with a vertical embedded flip chip structure or a vertical embedded chip structure, it has the advantages such as high brightness, low power consumption, high contrast, wide viewing angle, and the like. Therefore, when the electronic device ED serves as the vehicle display, the driver may more quickly understand the information displayed by the electronic device ED through the windshield WH, thereby reducing the possibility of risk of driving due to shifting of driver's sight.

In summary, a manufacturing method of an electronic device is provided by the present disclosure. The method includes transferring the electronic units by using fluid transfer and repairing the electronic units through laser transfer. Therefore, the waste of the electronic units may be reduced, or the yield of the electronic device may be improved. In addition, a manufacturing method of an electronic device is further provided by the present disclosure. The method includes transferring the electronic units to a substrate by using fluid transfer and transferring a portion of the electronic units EU on the substrate to another substrate. Therefore, the waste of the electronic units may be reduced, or the manufacturing process of the electronic device may be simplified, or the production cost of the electronic device may be reduced. Moreover, the manufacturing method of the electronic device of the present disclosure may further include performing the packaging process on the semiconductor elements before the fluid transfer process, such that the semiconductor elements include the vertical embedded flip chip structure or the vertical embedded chip structure, which facilitates the bonding of the packaged semiconductor elements on the target substrate in the fluid transfer process.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a plurality of semiconductor elements;
performing a packaging process on the plurality of semiconductor elements to form a plurality of packaged semiconductor elements, wherein the packaging process comprises:
disposing a plurality of filling material layers respectively on a sidewall of each of the plurality of semiconductor elements;
providing a substrate, wherein the substrate includes a plurality of working areas, and each of the plurality of working areas includes at least one first recess; and
disposing the plurality of packaged semiconductor elements in the at least one first recess of each of the plurality of working areas through fluid transfer.

2. The manufacturing method of claim 1, wherein each of the plurality of working areas further includes at least one second recess.

3. The manufacturing method of claim 2, further comprising following steps:
identifying a defective working area from the plurality of working areas, wherein at least one of the at least one first recess of the defective working area has no packaged semiconductor element or a defective packaged semiconductor element disposed therein; and
disposing at least one repairing packaged semiconductor element in at least one of the at least one second recess of the defective working area.

4. The manufacturing method of claim 1, wherein the packaging process further comprises:
disposing a first electrode on a first surface of each of the plurality of semiconductor elements;
disposing a conductive layer on a sidewall of each of the plurality of filling material layers; and
disposing a second electrode on a second surface of each of the plurality of semiconductor elements, wherein the second surface is opposite to the first surface.

5. The manufacturing method of claim 4, wherein in each of the plurality of packaged semiconductor elements, the conductive layer contacts the second electrode.

6. The manufacturing method of claim 4, wherein each of the plurality of filling material layers includes a third surface and a fourth surface opposite to the third surface, the third surface is adjacent to the first surface, the fourth surface is adjacent to the second surface, and the second electrode extends on the fourth surface.

7. The manufacturing method of claim 6, wherein the conductive layer extends on the third surface.

8. The manufacturing method of claim 1, wherein the plurality of packaged semiconductor elements have circular outlines in a top view of the electronic device.

9. A manufacturing method of an electronic device, comprising:
providing a plurality of semiconductor elements;
performing a packaging process on the plurality of semiconductor elements to form a plurality of packaged semiconductor elements, wherein the packaging process comprises:
disposing a plurality of filling material layers respectively on a sidewall of each of the plurality of semiconductor elements;
providing a first substrate, wherein the first substrate includes a plurality of recesses;
disposing the plurality of packaged semiconductor elements in the plurality of recesses of the first substrate through fluid transfer;
providing a second substrate, wherein the second substrate includes a plurality of working areas; and
transferring at least a portion of the plurality of packaged semiconductor elements from at least a portion of the plurality of recesses of the first substrate to the plurality of working areas.

10. The manufacturing method of claim 9, wherein the plurality of recesses have a first pitch, the plurality of working areas have a second pitch, and the second pitch is greater than the first pitch.

11. The manufacturing method of claim 9, wherein the packaging process further comprises:
disposing a first electrode on a first surface of each of the plurality of semiconductor elements;
disposing a conductive layer on a sidewall of each of the plurality of filling material layers; and
disposing a second electrode on a second surface of each of the plurality of semiconductor elements, wherein the second surface is opposite to the first surface.

12. The manufacturing method of claim 11, wherein in each of the plurality of packaged semiconductor elements, the conductive layer contacts the second electrode.
